(19) United States
(12) Patent Application Publication
(10) Pub. No.: US 2023/0298936 A1
(43) Pub. Date: Sep. 21, 2023

(54) COMBINED SELF-FORMING BARRIER AND SEED LAYER BY ATOMIC LAYER DEPOSITION

(71) Applicant: Lam Research Corporation, Fremont, CA (US)

(72) Inventors: Kyle Jordan Blakeney, Fremont, CA (US); Yezdi Dordi, Palo Alto, CA (US)

(21) Appl. No.: 18/041,391

(22) PCT Filed: Aug. 10, 2021
(86) PCT No.: PCT/US2021/045436

§ 371 Date: Feb. 10, 2023

Related U.S. Application Data
(60) Provisional application No. 62/706,397, filed on Aug. 13, 2020.

(51) Int. Cl. H01L 21/768; H01L 23/532; C23C 16/18; C23C 16/455; C23C 16/02; C23C 28/02; C23C 16/04; C25D 5/02; C25D 7/12

(52) U.S. Cl. CPC H01L 21/76846; H01L 23/53238; H01L 21/76877; C23C 16/18; C23C 16/45527; C23C 16/0272; C23C 16/45553; C23C 28/025; C23C 16/045; C25D 5/02; C25D 7/123

(57) ABSTRACT

An electrically conductive structure in an integrated circuit (IC) includes recessed features in a dielectric layer filled with metal. The recessed features include a conformal, self-forming diffusion barrier and seed layer to limit oxidation of the metal into ions that will diffuse through the dielectric. The self-forming diffusion barrier and seed layer may also form a surface oxide layer that can be removed by an acidic solution

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor devices may be formed in a multi-level arrangement with electrically conductive structures in different levels insulated from each other by one or more intervening layers of dielectric material. The formation of electrically conductive structures in the semiconductor devices can be achieved using damascene or dual damascene processes. Trenches and/or holes are etched into the dielectric material and are lined with one or more electrically conductive “seed” or “liner” layers and diffusion barrier layers. Electrically conductive material is then deposited in the trenches and/or holes to form vias, contacts, or other interconnect features that extend through the dielectric material and provide electrical interconnection between the electrically conductive structures.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Disclosed herein are methods and systems of depositing a layer, the method including: receiving a metallization layer having recessed features within a dielectric layer including a dielectric material; conformally depositing one or more layers collectively including copper and zinc over the recessed features, wherein conformally depositing at least one layer of the one or more layers includes a copper atomic layer deposition (ALD) process; and filling the recessed features with a metal.

In some embodiments, the method further includes causing zinc to diffuse from the one or more layers into the dielectric layer. In some embodiments, further including, prior to forming the metal layer in the recessed features, annealing the one or more layers at a temperature of at most about 250° C. In some embodiments, annealing the one or more layers is performed in the presence of hydrogen. In some embodiments, the one or more layers are electrically conductive and wherein at least one of the one or more layers provides a barrier to diffusion of metal ions from a metal layer to the dielectric material. In some embodiments, the method further includes forming a zinc silicate layer between the dielectric layer and the one or more layers. In some embodiments, the zinc silicate layer inhibits the diffusion of copper into the dielectric layer. In some embodiments, forming the zinc silicate layer occurs within the dielectric layer and/or at the interface of the dielectric layer and the one or more layers while conformally depositing the one or more layers over the recessed features. In some embodiments, forming the zinc silicate layer occurs within the dielectric layer and/or at the interface of the dielectric layer and the one or more layers after conformally depositing the one or more layers over the recessed features.

In some embodiments, the zinc silicate layer is about 2 nm thick or thinner. In some embodiments, further including forming a zinc oxide layer disposed on top of the one or more layers. In some embodiments, forming the zinc oxide layer includes exposing the one or more layers to the atmosphere. In some embodiments, conformally depositing the one or more layers includes depositing a copper-zinc alloy by a copper-zinc ALD process. In some embodiments, the copper-zinc ALD process includes: exposing the substrate to a zinc precursor, purging the zinc precursor, exposing the substrate to a copper precursor, and purging the copper precursor. In some embodiments, conformally depositing the one or more layers includes: exposing the substrate to a zinc precursor, purging the zinc precursor, exposing the substrate to a copper precursor, purging the copper precursor, exposing the substrate to a nitrogen containing reactant, and purging the nitrogen containing reactant. In some embodiments, conformally depositing the one or more layers includes: exposing the substrate to a copper precursor, purging the copper precursor, exposing the substrate to a nitrogen-containing reactant, and purging the nitrogen containing reactant, and depositing zinc by a chemical vapor deposition (CVD) process in the presence of hydrogen.

In some embodiments, conformally depositing the one or more layers includes: depositing a first zinc layer on the dielectric material, and depositing a copper layer by an ALD process. In some embodiments, conformally depositing the one or more layers further includes (c) depositing a second zinc layer on the copper layer. In some embodiments, conformally depositing the one or more layers includes: (a) exposing the substrate to a zinc precursor, (b) purging the zinc precursor, (c) exposing the substrate to a copper precursor, (d) purging the copper precursor, and (e) repeating (a)-(d) one or more times to form a copper-zinc layer, and (f) depositing a zinc layer. In some embodiments, the zinc precursor is a dialkyl zinc. In some embodiments, the copper precursor includes a bidentate ligand bound to copper via at least one oxygen atom. In some embodiments, the method further includes prior to depositing the one or more layers, conformally depositing a liner layer over the recessed features. In some embodiments, the liner layer includes at least one material chosen from the group consisting of: zinc, tantalum, titanium, tungsten, molybdenum, and their nitrides, carbides, and carbonitrides.

In some embodiments, filling the recessed features is performed by an electrodeposition process. In some embodiments, the metal is copper that is substantially free of zinc. In some embodiments, at least some of the recessed features have an aspect ratio of at least about 5:1. In some embodiments, at least some of the recessed features having an aspect ratio of at least about 5:1 have a width or diameter of about 20 nm or smaller. In some embodiments, the dielectric material has a dielectric constant of about 3.0 or lower.

In another aspect of the embodiments herein, a device is disclosed, the device including: a dielectric layer including a dielectric material and having recessed features, wherein at least some of the recessed features have a critical dimension of about 20 nm or smaller; one or more layers including at least one of copper and zinc conformally formed in the dielectric layer; and electrically conductive material formed in the recessed features, wherein the electrically conductive material is substantially zinc-free. In some embodiments, the self-forming diffusion barrier and electrically conductive seed layer is deposited by an ALD process. In some embodiments, the one or more layers provide a diffusion barrier to copper ions or copper metal atoms transporting from the electrically conductive material to the dielectric material. In some embodiments, further including a zinc silicate layer between the dielectric layer and the one or more layers. In some embodiments, the zinc silicate layer inhibits diffusion of copper into the dielectric layer. In some embodiments, the zinc silicate layer is about 2 nm thick or thinner. In some embodiments, further including a liner layer over the recessed features. In some embodiments, the liner layer includes at least one material chosen from the group consisting of: zinc, tantalum, titanium, tungsten, molybdenum, and their nitrides, carbides, and carbonitrides.

In some embodiments, at least some of the recessed features have an aspect ratio of at least about 5:1. In some embodiments, at least some of the recessed features having an aspect ratio of at least about 5:1 have a width or diameter of about 20 nm or smaller. In some embodiments, the dielectric material is an oxide. In some embodiments, the dielectric material has a dielectric constant less than about 3.0.

In another aspect of the embodiments herein, an apparatus is disclosed, the apparatus including: a reaction chamber configured to hold a substrate during a conformal deposition reaction on a substrate having recessed features within a dielectric layer including a dielectric material; and a controller that includes one or more processors and one or more memory devices, wherein the one or more memory devices store computer-executable instructions for controlling the one or more processors to: receive the substrate in the reaction chamber; conformally deposit one or more layers collectively including copper and zinc over the recessed features, wherein conformally depositing at least one layer of the one or more layers includes a copper atomic layer deposition (ALD) process; and transfer the substrate to an electroplating cell. In some embodiments, the computer-executable instructions further include instructions to cause zinc to diffuse from the one or more layers into the dielectric layer. In some embodiments, wherein the computer-executable instructions further include instructions to, prior to forming the metal layer in the recessed features, anneal the substrate at a temperature of at most about 250° C.

In some embodiments, annealing the substrate is performed in the presence of hydrogen. In some embodiments, the one or more layers are an electrically conductive layer and wherein at least one of the one or more layers provides a diffusion barrier to copper ions transporting from a metal layer to the dielectric material. In some embodiments, the computer-executable instructions further include instructions to form a zinc silicate layer between the dielectric layer and the one or more layers. In some embodiments, the zinc silicate layer is about 2 nm thick or thinner. In some embodiments, the computer-executable instructions further include instructions to form a zinc oxide layer on top of the one or more layers by exposing the one or more layers to the atmosphere. In some embodiments, the computer-executable instructions to deposit the one or more layers further include instructions to deposit a copper-zinc alloy by a copper-zinc ALD process.

In some embodiments, the computer-executable instructions to deposit a copper-zinc alloy by a copper-zinc ALD process include: exposing the substrate to a zinc precursor, purging the zinc precursor, exposing the substrate to a copper precursor, and purging the copper precursor. In some embodiments, the zinc precursor is diethyl zinc. In some embodiments, the copper precursor includes a bidentate ligand bound to copper via at least one oxygen atom. In some embodiments, the computer-executable instructions further include instructions to conformally deposit the one or more layers by: exposing the substrate to a copper precursor, purging the copper precursor, exposing the substrate to a zinc precursor, purging the zinc precursor, exposing the substrate to a nitrogen containing reactant, and purging the nitrogen containing reactant. In some embodiments, the computer-executable instructions further include instructions to conformally deposit the one or more layers by: exposing the substrate to a copper precursor, purging the copper precursor, exposing the substrate to a nitrogen-containing reactant, and purging the nitrogen-containing reactant, and depositing zinc by a chemical vapor deposition (CVD) process in the presence of hydrogen. In some embodiments, the computer-executable instructions further include instructions to conformally deposit the one or more layers by: depositing a first zinc layer on the dielectric material, and depositing a copper layer by an ALD process. In some embodiments, the computer-executable instructions to conformally deposit the one or more layers further includes depositing a second zinc layer on the copper layer. In some embodiments, the computer-executable instructions further include instructions to conformally deposit the one or more layers by: (a) exposing the substrate to a zinc precursor, (b) purging the zinc precursor, (c) exposing the substrate to a copper precursor, (d) purging the copper precursor, and (e) repeating (a)-(d) one or more times to form a copper-zinc layer, and (f) depositing a zinc layer. In some embodiments, the metal is copper that is substantially free of zinc.

In some embodiments, further including the electroplating cell, wherein the electroplating cell is configured to electroplate a metal into the recessed features of the substrate, and wherein the computer-executable instructions further include instructions to: electroplate the recessed features with a metal.

These and other features of the disclosed embodiments will be described in detail below with reference to the associated drawings.

### BRIEF DESCRIPTION OF DRAWINGS

FIG. 1 presents a cross-sectional illustration of a semiconductor device having various layers within a recessed feature.

FIG. 2 presents a cross-sectional illustration of a semiconductor device having a self-forming barrier and seed layer as described herein.

FIG. 3 presents a cross-sectional illustration of a semiconductor device having a self-forming barrier and seed layer on top of a liner.

FIG. 4 presents an enlarged view of a self-forming barrier and seed layer as described herein.

FIG. 5 presents a cross-sectional illustration of a semiconductor device having filled features.

FIGS. 6-11 present various process flow diagrams for embodiments discussed herein.

FIG. 12 presents various precursor chemistries that may be used for various embodiments described herein.

FIGS. 13-19 are schematic diagrams of examples of process chambers for performing methods in accordance with disclosed embodiments.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Fabrication of electrically conductive structures in semiconductor devices involves depositing metal lines and vias. These electrically conductive structures traverse horizontal distances across a chip, and interconnect vertically separated features (e.g., by vias) in different levels or layers. The line features may include copper lines and the interconnect features may include copper vias. The line features and interconnect features may be insulated by interlayer dielectrics (ILD) which are electrical insulators.

Integrated circuit (IC) fabrication methods commonly involve deposition of metals into recessed features formed in an ILD layer. The deposited metal provides the conductive paths which extend horizontally and/or vertically within the IC. A stack containing multiple layers of metal lines electrically connected to each other by one or more vias may be formed by a process known as damascene or dual damascene processing.

The metal used to fill features may include copper, cobalt, ruthenium, tungsten, nickel, molybdenum, rhodium, iridium, or alloys thereof. While copper is referred to throughout the specification, it should be understood that other suitable metals may be used. While the methods, apparatuses, and devices described below may be presented in the context of damascene processing, it will be understood that the methods, apparatuses, and devices of the present disclosure are not limited to damascene processing and may be used in the context of other processing methods.

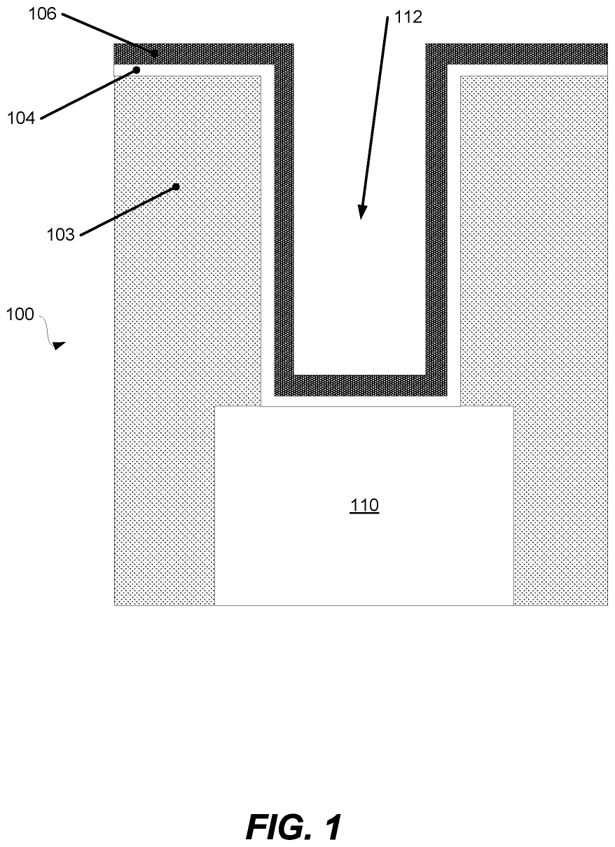

FIG. 1 provides a cross-sectional view of a metallization layer 100 showing elements of a partially fabricated integrated circuit. In some implementations, the metallization layer 100 may reside on include a layer carrying active devices, such as transistors, or include an underlying metallization layer containing copper or other type of metallization, such as metal line 110. The metallization layer 100 may include a dielectric layer 103. In some embodiments, the dielectric layer 103 is an oxide-based layer. In some implementations, the dielectric layer 103 includes a fluorine-doped or carbon-doped silicon oxide or an organic-containing low-k material such as an organosilicate glass (OSG). The dielectric layer 103 includes recesses 112 providing line paths through the dielectric layer 103, where the recesses 112 may be vias and trenches. The dielectric layer 103 may also include field regions outside of the recesses 112. As shown in FIG. 1, dielectric layer 103 may also surround metal line 110. In some embodiments, dielectric layer 103 may include an interlayer dielectric or multiple layers (not shown). As used herein, metal layers such as the deposited copper and associated dielectric layer may be referred to as metallization layers. The copper filling the trenches and vias may be referred to as metal lines, or line features.

A diffusion barrier layer 104 is provided on the metallization layer surface and follows the contours of the recesses 112. The diffusion barrier layer 104 serves to protect the dielectric layer 103 and underlying active devices from diffusion of copper. Examples of diffusion barrier materials include but are not limited to titanium (Ti), tantalum (Ta), tantalum nitride (TaN), titanium nitride (TiN), and fluorine-free tungsten (FFW). The diffusion barrier layer 104 may be deposited in the recesses 112 by any suitable deposition technique such as physical vapor deposition (PVD), atomic layer deposition (ALD), chemical vapor deposition (CVD), electroplating, and plasma enhanced chemical vapor deposition (PECVD).

An electrically conductive seed layer or liner 106 is provided on the metallization layer surface, on top of the diffusion barrier layer. The liner provides a conductive surface on which a subsequent electroplating reaction may be initiated. A liner layer may be made of a conductive material such as cobalt or ruthenium. In some embodiments the liner layer is made of the metal to be plated, such as copper. Liner layers may be formed using any suitable deposition method such as PVD, ALD, CVD, or PECVD. Together, a diffusion barrier layer and/or liner layer serve to slow diffusion of metal into adjacent dielectric material, improve device lifetime, improve adhesion, and limit the formation of stress-induced voids, among other functions.

The recesses 112 providing the etched line paths are filled with metal. Conventionally, a thin copper seed layer is deposited on the diffusion barrier layer 104, e.g., seed layer 106, followed by bulk electrodeposition of copper to fill the recesses 112. This forms copper lines and interconnects within the recesses 112.

As has been happening throughout the history of semiconductor device circuit design, feature sizes continue to shrink. As a result, interconnect feature sizes and via sizes also continue to shrink. This presents many challenges during fabrication and maintaining device performance and reliability. For example, PVD copper seed layers and PVD Ta or TaN diffusion barrier layers have relatively poor step coverage, which presents an increasing challenge in features having small width and/or high aspect ratio. The film thickness needed to achieve sufficient barrier and seed layer performance does not allow enough room for conductive lines in devices having critical dimensions less than about 25 nm, e.g. 22 nm.

### Description of the Combined Diffusion Barrier and Seed Layer

Presented herein are methods of depositing a self-forming diffusion barrier and seed layer for metallization. In some embodiments, a self-forming diffusion barrier and seed layer is a single layer or multiple layers that function as a diffusion barrier and a seed layer via a self-forming mechanism. In some embodiments, a self-forming diffusion barrier and seed layer may be formed by depositing a conformal copper-zinc layer by, e.g., an ALD process onto a dielectric layer. The use of copper and zinc may provide various benefits, including a self-forming diffusion barrier, increased adhesion/more continuous film, a protective oxide surface that may be removed prior to electroplating, and nominal increase to resistivity. Only a single layer need be deposited in order to provide both seed and barrier functions, which preserves much needed volume for conductive current carrying lines.

In certain embodiments, a copper-zinc layer is deposited on a dielectric-containing surface of a substrate and allowed to interact with the substrate in a way that produces a zinc-containing diffusion barrier between the dielectric and the copper-zinc layer. In certain embodiments, the diffusion barrier is a zinc silicate layer, although diffusion barriers of other compositions may be produced depending on the composition of the dielectric layer on which the copper-zinc layer is deposited. In some cases, deposited copper-zinc layer is permitted to interact with the ambient and form a protective zinc oxide layer. In some implementations, materials other than zinc or copper may be used in the self-forming diffusion barrier and conductive seed layer may be employed. In some cases, the self-forming diffusion barrier and conductive seed layer includes a first metal and a second metal, where the second metal is present in lower concentration than the first metal and reacts more readily with the dielectric than the first metal. The second metal may also be relatively more mobile (e.g., have a larger diffusivity) than the first metal in the self-forming diffusion barrier and conductive seed layer.

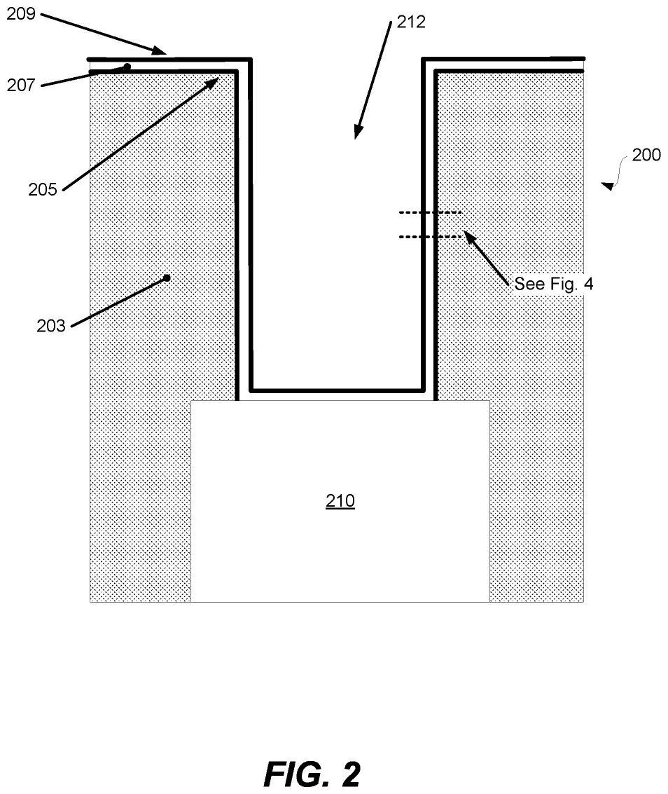

FIG. 2 presents an illustration of a metallization layer 200 having a self-forming diffusion barrier and seed layer 207. As should be clear, the self-forming diffusion barrier and seed layer 207 comprises copper and zinc and may be referred to as a copper-zinc layer. The metallization layer 200 has a metal line 210 and a dielectric layer 203. The dielectric layer includes a feature 212, into which layer 207 is conformally deposited. At the interface between the self-forming diffusion barrier and seed layer 207 and the dielectric layer 203 is a silicate layer 205. The silicate layer may form due to a reaction between zinc atoms in layer 207 and the dielectric material in the dielectric layer 203, which serves as an oxidizing agent. Zinc atoms may diffuse into the dielectric layer 203 and react with hydroxy groups to form silicate layer 205. Notably, a silicate layer may not form at the interface between the metal line 210 and the diffusion barrier and seed layer 207. The silicate layer 205 may inhibit the oxidation of copper and/or inhibit the movement of copper or zinc ions into the dielectric.

In this example, at the interface between layer 207 and the ambient, a zinc oxide layer 209 is formed. As with formation of the silicate layer 205, zinc preferentially oxidizes over copper due to a lower electronegativity. Therefore, exposure of the copper zinc layer to ambient will form a zinc oxide layer. Zinc oxide layer 209 may provide a stable, protective layer that assists in maintaining a continuous conductive seed layer (which may still have some amount of zinc) for initiating high quality electrofill.

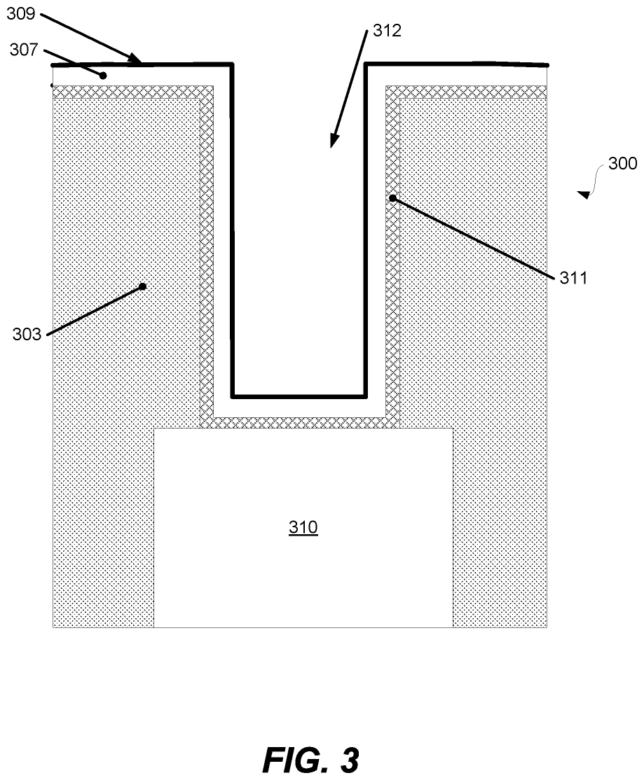

FIG. 3 presents an illustration of a metallization layer 300 having a self-forming diffusion barrier and seed layer 307. Consistent with other embodiments, the self-forming diffusion barrier and seed layer 307 may comprise copper and zinc. The metallization layer 300 has a metal line 310 and a dielectric layer 303. The dielectric layer includes a feature 312, into which layer 307 is conformally deposited. At the interface between the self-forming diffusion barrier and seed layer 307 and ambient is a zinc oxide layer 309. The main distinction between metallization layer 300 and metallization layer 200 is the presence of a liner 311 conformally deposited between the dielectric layer 303 and the self-forming diffusion barrier and seed layer 307. The liner 311 may serve various purposes. In some embodiments, it may increase adhesion between the dielectric layer 303 and the self-forming diffusion barrier and seed layer 307. For example, the liner may be ruthenium, cobalt, molybdenum or tungsten. In some embodiments, the liner may be less than about 1 nm thick, less than about 50 Å thick, or less than about 10 Å thick. In other embodiments, liner 307 may act as an additional diffusion barrier. Examples of diffusion barrier materials include but are not limited to zinc (Zn), titanium (Ti), tantalum (Ta), tungsten (W), molybdenum (Mo), and their corresponding nitrides, carbides, or carbonitrides.

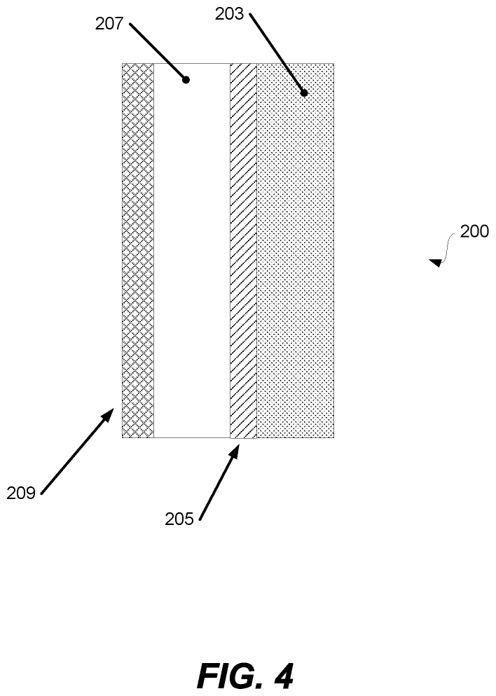

FIG. 4 provides a magnified view of metallization layer 200, specifically showing the dielectric layer 203, the silicate layer 205, the copper-zinc layer 207, and the zinc oxide layer 209. As can be seen, a small interfacial zinc silicate layer is formed between the copper-zinc layer and the dielectric. As mentioned, it is believed that the zinc silicate layer inhibits the oxidation of copper and/or restricts the movement of copper ions into the dielectric, both of which are undesirable. On the other side, a zinc oxide layer protects the zinc-copper layer 207. As noted above, one advantage of a self-forming diffusion barrier and seed layer as described herein, namely a zinc-copper layer, may be that both the zinc silicate and zinc oxide reactions are self-limiting. Both layers act to preserve the zinc-copper layer 207, allowing for a thinner deposition while still maintaining a continuous film. Furthermore, the copper-zinc layer 207 as well as the silicate layer 205 and the zinc oxide layer 209 may be continuous, without forming agglomerations. This may be advantageous during a later electrodeposition step, where agglomeration may result in the formation of voids during electrodeposition. A continuous film may reduce the size and/or presence of voids, which is desirable.

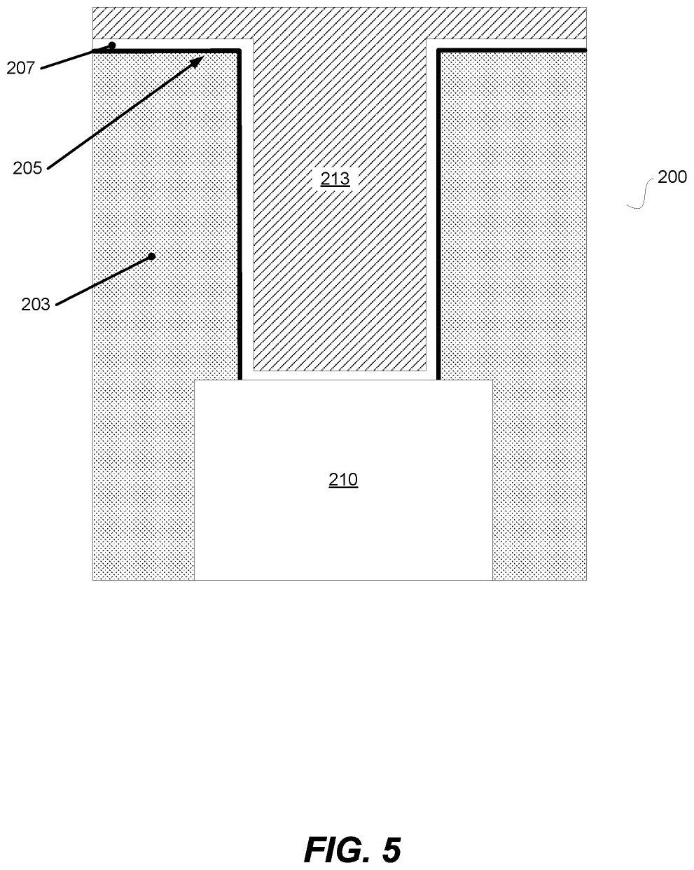

FIG. 5 provides an illustration of metallization layer 200 after metallization, where feature 212 is filled with metal to form a metal line 213. In some embodiments, the metallization layer 200 after deposition may not include zinc oxide layer 209. Either prior to or when the metallization layer 200 is immersed in the electroplating bath, the zinc oxide layer 209 is removed, exposing the copper-zinc layer 207 for electroplating. Thus, the filled features may not include a zinc oxide layer. In some embodiments, the metal line 213 is substantially copper, or is substantially without zinc, for example at least 99.5% copper. This may be due to the plating solution not containing any zinc ions.

While the incorporation of zinc into a copper film has generally been viewed negatively due to increasing resistivity and causing electrical malfunctions due to zinc diffusion, the present inventors realized it may present various advantages for a self-forming diffusion barrier and seed layer. Specifically, a copper-zinc self-forming diffusion barrier and seed layer may be advantageous for back-end of line (BEOL) metallization of features having a critical dimension of about 20 nm or less or about 15 nm or less.

As described above, a metallization layer typically includes separate barrier and seed layers. The barrier layer inhibits the transport of copper ions into a dielectric layer, where they can hinder electrical performance. The seed layer provides an electrically conductive surface that allows electroplating to begin on an otherwise insulating surface. If the seed layer includes gaps in coverage of the dielectric layer, the subsequently electroplated metal may have voids which are detrimental to bottom-up fill and conductivity.

Similar to copper, zinc may oxidize at the interface with a dielectric. However, with a copper/zinc layer, zinc is believed to react preferentially due, in part, to zinc's more negative reduction potential and preferential diffusion into the dielectric. When zinc reacts at the dielectric interface, it may form a thin zinc silicate layer within the dielectric layer that remains in place at the interface. In other words, the zinc in the layer does not migrate further into the dielectric where it could degrade the electrical properties of the associated device. Copper, on the other hand, can react at the interface with the dielectric material and oxidizes to form copper ions which are mobile and diffuse into the dielectric where they may degrade the electric properties of the associated device. Without wishing to be bound to a particular theory, it is believed that zinc diffuses to the dielectric material where it is preferably oxidized over copper, forming a zinc silicate layer that inhibits the diffusion of copper ions and/or inhibits oxidation of copper metal to copper ions.

The zinc may react at the dielectric interface in a self-limiting manner. In other words, as more zinc becomes available, it does not continue to react or be consumed at the interface. Thus, while acting as a copper diffusion barrier, the zinc silicate does not occupy undue volume in the feature.

The zinc silicate may prevent the copper metal from contacting to or diffusing to the dielectric, and thus prevent the copper metal from oxidizing to form copper ions. While not wishing to be bound by a particular theory, it is believed that prevention of Cu oxidation at the dielectric interface yields improved barrier performance under electrical stress tests. By blocking the reaction of copper(0) into copper(II) or copper(I), the zinc silicate may fully or partially serve its role as a diffusion barrier.

Another benefit to incorporating zinc is improving adhesion. The zinc helps the copper form a continuous film on the dielectric layer. Often direct deposition of copper onto dielectric (e.g., silicon oxide) results in the copper forming blobs or agglomerates rather than a continuous thin film. In this conventional approach, the balance between adhesion and cohesion is strongly biased toward cohesion. It is believed that the addition of zinc in the deposited film promotes adhesion and hence makes a more continuous layer. The presence of the zinc silicate at the interface between the seed layer and the dielectric improves the adhesion of the seed layer to the dielectric. In experiments, a stack of copper-zinc/ruthenium/silicon oxide is believed to provide an energy of adhesion of above 15 J/m², which is sufficient for subsequent metal plating. For comparison, a copper/ruthenium/silicon oxide stack has an energy of adhesion below 3 J/m² which results in the metal film delaminating from the dielectric during subsequent processes.

In certain embodiments, the zinc/copper layer may have a coating of zinc oxide or related compound on an exposed surface (i.e., the surface opposite the dielectric material). In certain embodiments, the zinc oxide or related material forms when the zinc/copper layer is exposed to the atmosphere. In comparison to copper, the zinc in the copper zinc layer may preferentially oxidize at the exposed surface of the layer; that is, the surface that is exposed to the ambient. Thus, if a metallization layer coated with a copper zinc layer is exposed to oxygen in the atmosphere, zinc oxide will preferentially form on the surface. It is believed that the zinc oxide on the surface may protect underlying copper from oxidation. It is known that copper oxide on a seed layer is quickly dissolved upon immersion into an electroplating bath. The copper oxide that dissolves represents a loss of copper in the seed layer and possibly a condition in which seed layer fails to provide a conductive surface at certain regions of features to be plated. Elaborate precautions are sometimes undertaken to mitigate this dissolution. In contrast, when the zinc oxide contacts the electroplating bath, it may dissolve, but its loss does not represent a significant degradation of the seed layer. Thus, a continuous copper metal layer may be maintained for electroplating on.

### Properties of Metallization Layer

Various embodiments discussed herein relate to depositing a layer within recessed features of a dielectric layer. In some embodiments, the recesses into which a copper-zinc layer is conformally deposited have aspect ratios equal to or greater than about 2:1, equal to or greater than about 5:1, or equal to or greater than about 10:1. As noted above, it may be particularly difficult to plate into such features due to the small critical dimension, e.g. a critical dimension less than about 20 nm or less than about 12 nm. A copper-zinc layer described herein may be conformally deposited in such features without losing feature definition. In some embodiments the dielectric is an oxide-based dielectric, for example silicon oxide or silicon oxicarbide. In some implementations, the dielectric is a low-k dielectric material. A low-k dielectric material may be characterized by having a dielectric constant of less than about 4.0, less than about 3.0, between about 2.0 and 3.0, or between about 2.3 and 3.0. In some implementations, the dielectric layer includes a fluorine-doped or carbon-doped silicon oxide or an organic-containing low-k material such as an organosilicate glass (OSG).

### Properties of the Combined Diffusion Barrier and Seed Layer

A copper-zinc layer as described herein functions as a self-forming diffusion barrier and seed layer for electrodeposition. In some embodiments, the deposited copper-zinc film may be less than about 5 nm, less than about 3 nm, less than about 2 nm or less than about 50 Å. In certain embodiments, a zinc silicate layer that may form between the copper-zinc layer and a dielectric layer is about 2 nm or thinner. In certain embodiments, the zinc silicate thickness is about 1 nm or thinner. In some embodiments, the copper-zinc film has a resistance of less than about 1000 ohm/sq, less than about 500 ohm/sq, or about 300 ohm/sq.

In some embodiments, the copper-zinc layer is between about 1% and about 20% atomic zinc. In some cases, the copper-zinc layer includes zinc in a concentration of about 5 to 15% atomic. In some embodiments, the copper-zinc layer is significantly copper, for example at least 90% copper, or at least 95% copper. In some embodiments, the copper-zinc layer may include nitrogen, for example at most about 10% atomic nitrogen.

While this disclosure has mainly referred to self-forming diffusion barrier and seed layers having copper and zinc, one or both of these metals may be substituted. For example, zinc may be substituted or supplemented with aluminum, gallium and/or indium. It is believed that each of these will form a silicate preferentially to copper oxidation at the dielectric interface. In some embodiments, instead of a copper-zinc layer, a layer may be formed by Cu—Al, Cu—Ga or Cu—In ALD using a Cu precursor and a Al, Ga or In alkyl reactant, such as trimethylaluminum, triethylaluminum, trimethylgallium, triethylgallium, trimethylindium, and triethylindium. Further embodiments include ALD self-forming diffusion barrier and seed layers for cobalt metallization. In such embodiments, copper may be substituted or supplemented with cobalt. Analogous cobalt precursors may be used along with zinc, aluminum, gallium, or indium for depositing a self-forming diffusion barrier and seed layer.

### ALD Process

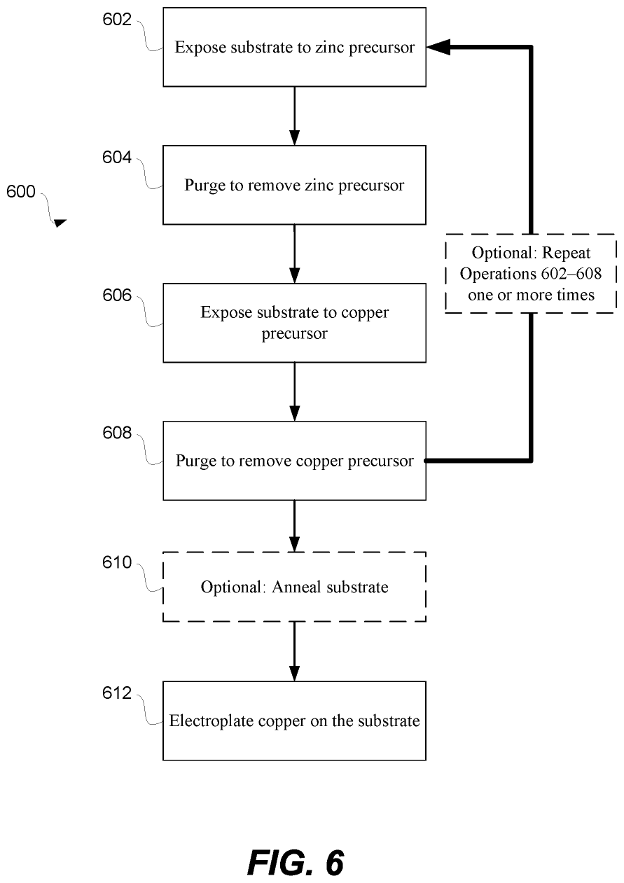

A copper-zinc layer as described herein functions as a self-forming diffusion barrier and seed layer for electrodeposition. A copper-zinc layer may be formed by various processes, including an ALD process. FIGS. 6-8 provide process flow diagrams for depositing a self-forming diffusion barrier and seed layer as described herein, particularly a copper-zinc layer, on a metallization layer. The metallization layer may be a substrate as described herein; having a dielectric layer with recessed features, a metal layer at the bottom of the recessed features, and in some embodiments a liner conformally deposited within the features.

FIG. 6 provides an ALD process 600. In operation 602, a substrate having a metallization layer is exposed to a Zn-containing vapor. In some embodiments, a Zn-containing vapor may be zinc atoms, e.g., as a result of evaporation or sputtering. In some embodiments, a Zn-containing vapor is a Zn-containing precursor. Zn-containing precursors are discussed elsewhere herein. Generally, the Zn-containing precursor will adsorb onto a surface of the metallization layer. In some embodiments, the Zn-containing precursor is diethyl zinc. In operation 604, a purge period removes excess precursor and any volatile by-products. In operation 606 the metallization layer is exposed to a Cu-containing precursor. Cu-containing precursors are discussed elsewhere herein. During operation 606, the Cu-containing precursor reacts with the adsorbed Zn-containing precursor. Following operation 606 is operation 608, where the process chamber is purged to remove excess reactant and any by-products. Operations 602-608 may be repeated one or more times to build a layer comprising copper-zinc. While much of the Zn-containing precursor may remain as a volatile molecule after reaction with the Cu-containing precursor, some Zn-containing precursor may interact with the metallization layer surface to deposit zinc, incorporating zinc into the growing film.

In some embodiments, an optional operation 610 is performed to anneal the substrate. Annealing is discussed further below, but generally may be used to increase the kinetics of zinc silicate formation between the dielectric layer and the copper-zinc layer.

In operation 612 the substrate is exposed to electroplating solution to deposit metal, e.g. copper, as described herein.

While the process flow 600 of Figure describes exposing the metallization layer to a Zn-containing precursor first in operation 602, it should be understood that operation 602 could instead be exposing the metallization layer to a Cu-containing precursor. Likewise, operation 606 would be exposing the metallization layer to a Zn-containing precursor. Furthermore, while FIG. 6 describes an ALD process of alternating exposure to copper- and zinc-containing precursors, in some embodiments multiple cycles of exposure to copper- or zinc-containing precursors may occur. In various embodiments, 2, 3, 4, or more cycles of copper-containing precursor exposure may be completed, followed by 2, 3, 4, or more cycles of zinc-containing precursor exposure.

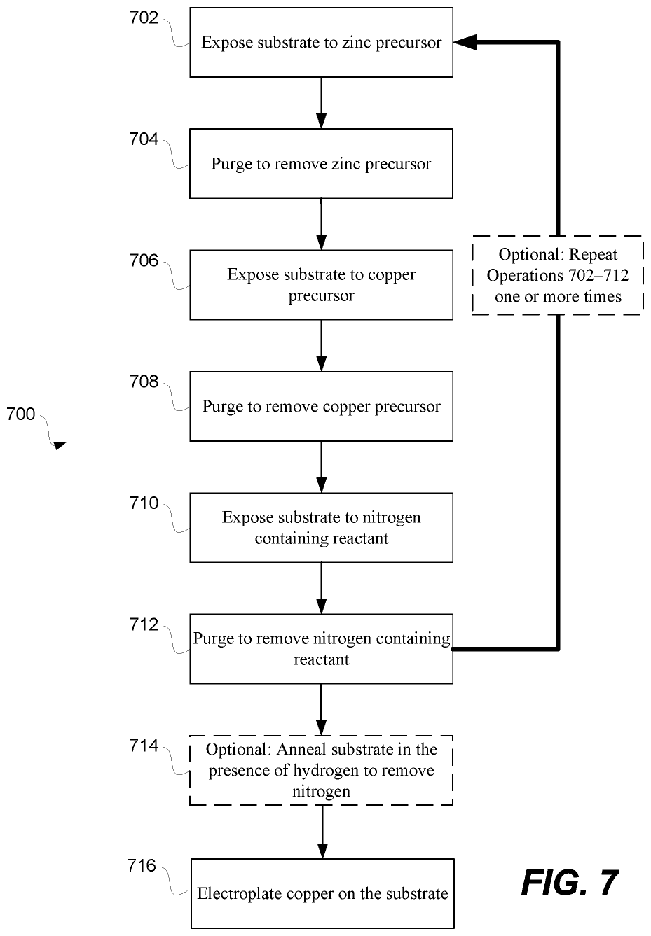

FIG. 7 provides a different process flow 700 for depositing a self-forming diffusion barrier and seed layer as described herein, in particular a copper-zinc layer. Operations 702-708 are similar to operations 602-608 in FIG. 6, and such discussion is incorporated here. In operation 710, the metallization layer is exposed to a nitrogen-containing reactant, such as NH₃. This may incorporate nitrogen into the film, which can help facilitate the deposition of copper and/or zinc and ensure an ultrathin continuous film. In operation 712, the process chamber is purged to remove nitrogen-containing reactant and any volatile by-products. Operations 702-712 comprise a single ALD cycle and may be repeated one or more times to build a layer comprising copper, zinc, and nitrogen.

Similar to process flow 600, above, the steps of exposure to a copper-containing reactant and a zinc-containing reactant may be switched. In some embodiments, it may be preferable to expose the metallization layer to a zinc-containing reactant after the exposure of the metallization layer to a copper-containing reactant and before the exposure of the metallization layer to a nitrogen-containing reactant. In such embodiments, this may reduce the formation of copper nitride, where the copper nitride is undesirable.

Operation 714 is an optional operation to anneal the substrate. Annealing is discussed further below, but may be performed in the presence of hydrogen to remove nitrogen from the deposited film. Nitrogen is generally undesirable for conductive layers of a semiconductor device, but may reduce agglomerization and ensure a continuous film. Annealing may then be employed to remove the nitrogen, leaving a copper-zinc layer as discussed herein.

In operation 712, the substrate is then exposed to electroplating solution to deposit metal into the features, e.g. copper, as described herein.

While FIG. 7 describes an ALD process of alternating exposure to zinc-, and copper-, and nitrogen-containing precursors, in some embodiments multiple cycles of exposure to copper-, zinc-, or nitrogen-containing precursors may occur. In various embodiments, 2, 3, 4, or more cycles of copper-containing precursor exposure may be completed, followed by 2, 3, 4, or more cycles of nitrogen-containing precursor exposure, followed by 2, 3, 4, or more cycles of zinc-containing precursor exposure.

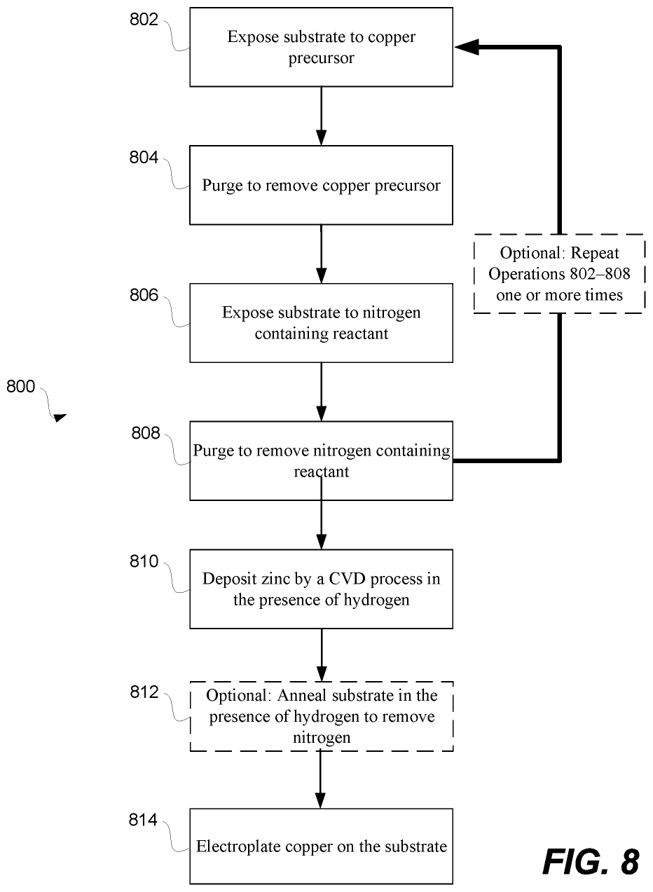

FIG. 8 provides a third process flow 800 for depositing a self-forming diffusion barrier and seed layer as described herein, in particular a copper-zinc layer. In contrast to FIGS. 7 and 8, a copper nitride film is first deposited by an ALD process, followed by a deposition of zinc in the presence of hydrogen to remove nitrogen and add zinc to the growing film. In operation 802, a substrate having a metallization layer is exposed to a Cu-containing precursor. The substrate may be a substrate as described herein; having a dielectric layer with recessed features, and in some embodiments a liner conformally deposited within the features. Cu-containing precursors are discussed elsewhere herein. Generally, the Cu-containing precursor will adsorb onto a surface of the metallization layer. In operation 804, a purge period removes excess precursor and any volatile by-products. In operation 806 the metallization layer is exposed to a nitrogen-containing reactant, such as NH₃. The nitrogen-containing reactant may react with the adsorbed copper precursor, forming a copper nitride. In operation 808, the process chamber is purged to remove the nitrogen-containing reactant and any volatile by-products. Operations 802-808 comprise a single ALD cycle that may be repeated one or more times to build a layer of copper nitride. In some embodiments, multiple ALD cycles may be performed before proceeding with a subsequent operation. For example, in some embodiments about 10, 100, or 1000 cycles are performed to deposit a copper nitride layer.

In operation 810, zinc is deposited by exposing the copper nitride film to a Zn-containing precursor. The operation may be performed in the presence of hydrogen to remove nitrogen from the film. The process temperature is in the range of 30-300° C., such as between 150-250° C., for example 200° C. The zinc may then be incorporated into the deposited film to form a copper-zinc layer.

Operation 812 is an optional operation to anneal the substrate. Annealing is discussed further below, but may be performed in the presence of hydrogen to further remove nitrogen from the deposited film. Nitrogen is generally undesirable for conductive layers of a semiconductor device, but may reduce agglomerization and ensure a continuous film. Annealing may then be employed to remove the nitrogen, leaving a copper-zinc layer as discussed herein.

In operation 814, the substrate is then exposed to electroplating solution to deposit metal into the features, e.g. copper, as described herein.

While FIG. 8 describes an ALD process of alternating exposure to zinc-, and copper-, and nitrogen-containing precursors, in some embodiments multiple cycles of exposure to copper-, zinc-, or nitrogen-containing precursors may occur. In various embodiments, 2, 3, 4, or more cycles of copper-containing precursor exposure may be completed, followed by 2, 3, 4, or more cycles of nitrogen-containing precursor exposure.

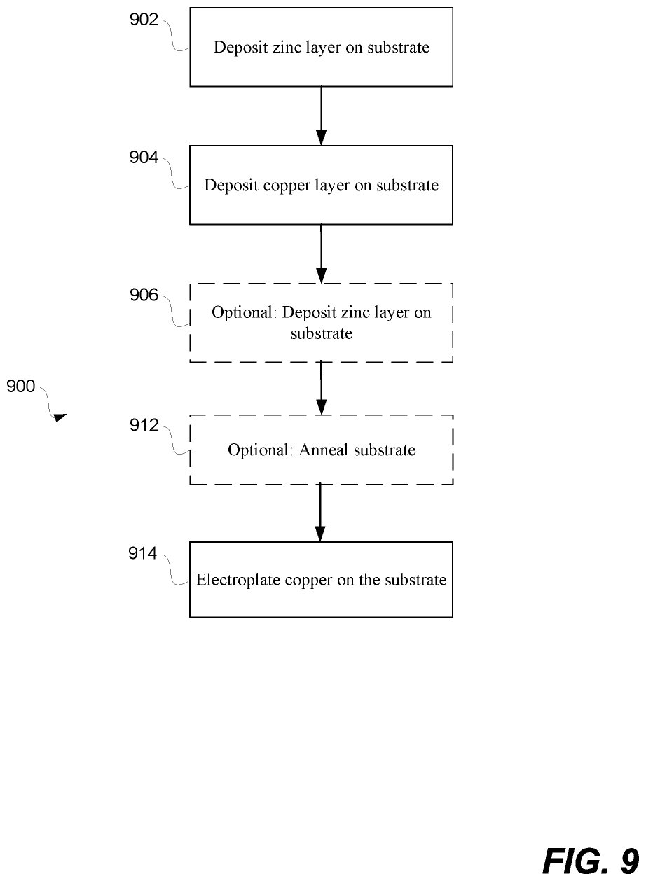

FIG. 9n provides a process flow 900 for depositing a diffusion barrier and seed layer as described herein. In operation 902, a zinc layer is deposited. This may be accomplished by a CVD, PVD, or ALD process as described herein. In operation 904, a copper layer is deposited. A copper layer may be deposited by an ALD process as described herein. Operation 906 is an optional operation to deposit a second zinc layer on the copper layer. Operation 906 may be accomplished using a similar or different process from depositing a zinc layer in operation 902.

In some embodiments, an optional operation 912 is performed to anneal the substrate. Annealing is discussed further below, but generally may be used to increase the diffusion rate of zinc and/or increase the kinetics of zinc silicate formation between the dielectric layer and the copper-zinc layer.

In operation 914 the substrate is exposed to electroplating solution to deposit metal, e.g. copper, as described herein.

Operations 902 and 904 may result in a zinc-copper bilayer. The layers may be distinct in that each layer is substantially zinc or copper, respectively. In embodiments where operation 906 is performed, operations 902, 904, and 906 may result in a zinc-copper-zinc trilayer. In some embodiments each layer may be substantially zinc or copper. In some embodiments operations 902 and 904 are performed in reverse, such that a copper layer is deposited, and then a zinc layer. In such embodiments operation 906 and 902 may be the same operation.

In some embodiments, depositing a bilayer of zinc and copper or a trilayer of zinc-copper-zinc may be advantageous to encourage zinc to diffuse towards the surface and/or react at the dielectric. In such embodiments, zinc may more readily form a silicate layer or more readily form a zinc oxide at the surface. In embodiments employing bilayers or trilayers of zinc and copper, a copper layer may be less than about 3 nm thick, while each zinc layer may be less than about 1 nm thick. In some embodiments, the thickness of the entire bilayer or trilayer may be less than about 5 nm.

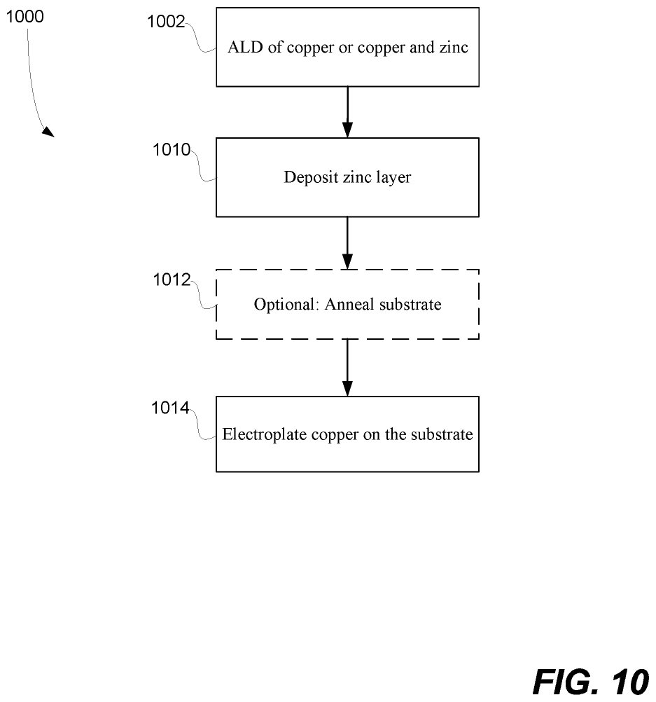

FIG. 10 provides another process flow for depositing a diffusion barrier and seed layer as described herein. In operation 1002, a copper or a copper and zinc layer is deposited by an ALD process. The ALD process may be a process as described elsewhere herein. In operation 1010, a zinc layer may be deposited on the zinc-copper layer. In some embodiments, zinc may be deposited in a manner similar to operation 810. In some embodiments, zinc may be deposited by a PVD process, e.g., evaporation or sputtering. In some embodiments, zinc vapor, rather than a zinc-containing precursor, may be used to deposit a zinc layer. In various embodiments zinc may be deposited by a thermal or plasma-based process. In some embodiments, multiple ALD cycles may be performed in operation 1002 before proceeding with a subsequent operation. For example, in some embodiments about 10,100, or 1000 cycles are performed to deposit a copper or copper-zinc layer.

In some embodiments, an optional operation 1012 is performed to anneal the substrate. Annealing is discussed further below, but generally may be used to increase the diffusion rate of zinc to the seed-dielectric interface and/or increase the kinetics of zinc silicate formation between the dielectric layer and the copper-zinc layer.

In operation 1014 the substrate is exposed to electroplating solution to deposit metal, e.g. copper, as described herein.

In some embodiments employing a copper zinc bilayer, annealing may be used to increase diffusion and/or reaction rate. In such embodiments, there may initially be an absence of zinc at the interface with the dielectric or surface due to the deposition of a bilayer. Annealing may facilitate zinc to diffuse across the copper layer to provide both a zinc oxide layer and a zinc silicate layer.

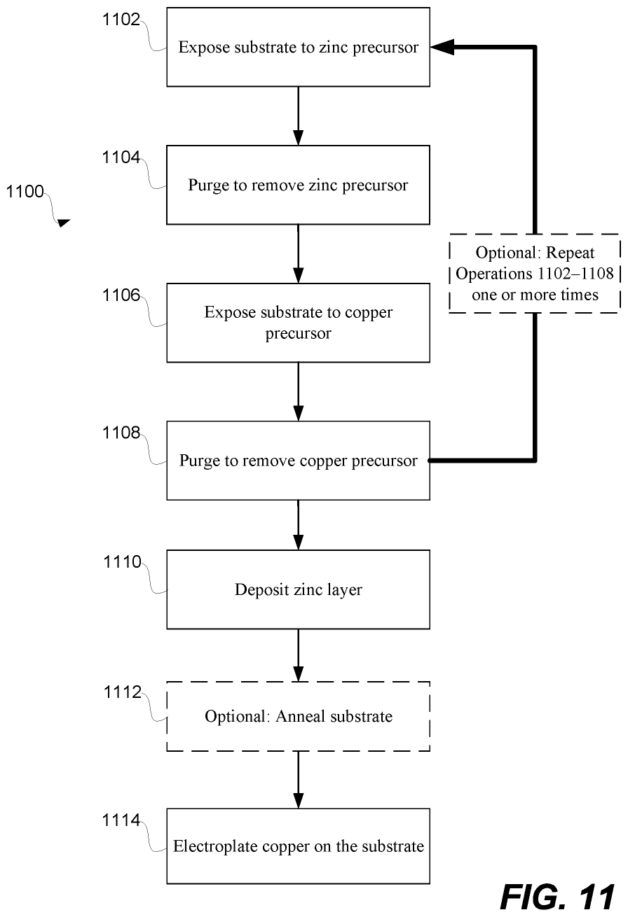

FIG. 11 provides another process flow for depositing a diffusion barrier and seed layer as described herein. Operations 1102-1108 are similar to operations 602-608, and such discussion is incorporated here. In operation 1110, a zinc layer may be deposited on the zinc-copper layer. In some embodiments, zinc may be deposited in a manner similar to operation 810. In some embodiments, zinc may be deposited by a PVD process, e.g., evaporation or sputtering. In some embodiments, zinc vapor, rather than a zinc-containing precursor, may be used to deposit a zinc layer. In various embodiments zinc may be deposited by a thermal or plasma based process.

In some embodiments, an optional operation 1112 is performed to anneal the substrate. Annealing is discussed further below, but generally may be used to increase the diffusion rate of zinc to the seed-dielectric interface and/or increase the kinetics of zinc silicate formation between the dielectric layer and the copper-zinc layer.

In operation 1114 the substrate is exposed to electroplating solution to deposit metal, e.g. copper, as described herein.

### ALD Parameters

ALD processes described herein include depositing copper via a reaction with zinc and copper precursors. Further discussion of ALD processes for depositing copper may be found in Lee, B. H. et al., Low-Temperature Atomic Layer Deposition of Copper Metal Thin Films: Self-Limiting Surface Reaction of Copper Dimethylamino-2-Propoxide with Diethylzinc. Angew. Chemie Int. Ed. 2009, 48, 4536-4539.

The temperature of the ALD processes may about 200° C. or less, or about 150° C. or less. In some embodiments, a zinc CVD process may be performed at a higher temperature, for example about 300° C. or less. In some embodiments, the copper nitride deposition process in FIG. 8 may be performed at about 200° C. or less.

In some embodiments, the total thickness of the self-forming diffusion barrier and seed layer may be about 5 nm or less, or about 3 nm or less, about 2 nm or less, or about 50 Å or less. In some embodiments, multiple ALD cycles are performed to achieve a desired film thickness, for example between about 1 and 100 cycles.

In some embodiments, the self-forming diffusion barrier and seed layer comprises three compositions: a zinc silicate composition at an interface with and/or within an upper surface of a dielectric layer, a copper-zinc composition, and a zinc oxide composition at the interface with the atmosphere. In some embodiments, the copper-zinc composition has a resistance less than about 1000 ohm/sq.

### Precursors

Suitable Cu and Zn precursors have a vapor pressure that allows them to be present in substantially vapor phase at the reaction chamber temperature. In addition to the description below, other suitable copper and zinc precursors are described in Gordon, P. G. et al, Trends in Copper Precursor Development for CVD and ALD Applications. ECS J. Solid State Sci. Technol. 2014, 4, N3188-N3197.

### Copper Precursors

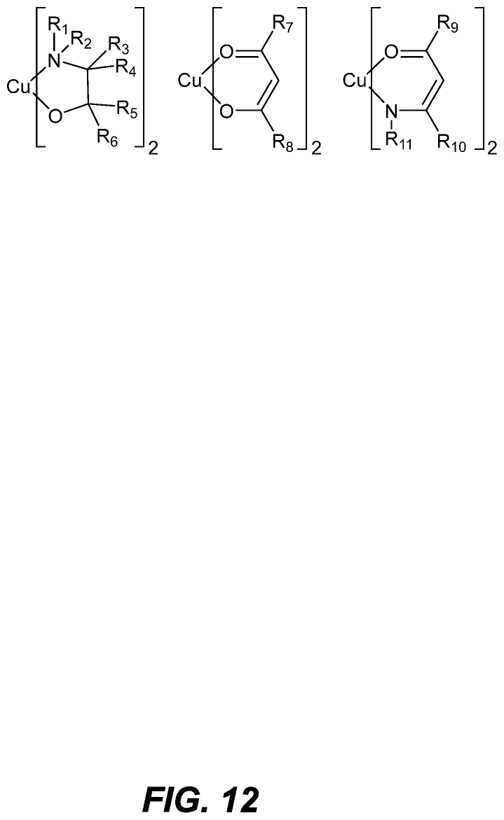

In certain embodiments, the copper precursor is an organo-copper compound. In certain embodiments, the copper precursor is an organometallic compound that contains copper in the valence two oxidation state, Cu(II). In certain embodiments, the copper precursor contains copper II and a bidentate ligand. In some embodiments the copper precursor has two separate ligands each separately attached to the copper atom. In certain embodiments, the copper precursor contains a bidentate ligand having oxygen bonded to the copper via at least one arm of the bidentate ligand. In certain embodiments, one arm of a bidentate ligand attaches to copper via oxygen and the other arm attaches via nitrogen. While not wishing to be bound to a particular theory, it is believed that copper precursors with ligands that are bound through at least one oxygen atom enable film deposition reactions with a zinc co-reactant. Examples of chemical structures for copper-containing precursors are provided in FIG. 12. In some embodiments, the copper-containing precursor includes a copper aminoalkoxide.

### Zinc Precursors

In certain embodiments, the zinc precursor is an organo- zinc compound. In certain embodiments, the zinc compound is a dihydrocarbyl zinc compound such as an alkylzinc compound or an allyl zinc compound. In certain embodiments, the zinc precursor is diethyl zinc. Other suitable zinc co-reactants include dimethylzinc, bis(allyl)zinc, bis(2-methylallyl)zinc, and derivatives thereof. Note that the two hydrocarbon groups attached to the zinc atom need not be the same. In certain embodiments, a group has between one and six carbon atoms. In certain embodiments, the zinc precursor contains one or more unsaturated groups attached to it. In some embodiment, the zinc precursor is a zinc vapor produced by, e.g., evaporation or sputtering.

### Post-ALD Treatments (e.g., Annealing and Electrodeposition)

Annealing may be performed after any of the self-forming diffusion barrier and seed layer depositions described herein. Annealing may improve the kinetics of zinc diffusing to the dielectric interface and forming a silicate. In some embodiments, a zinc silicate layer forms during an annealing process, rather than during the conformal deposition of the copper-zinc layer. Thus, annealing may be particularly useful as the temperature of the zinc deposition decreases. A post-deposition anneal may be employed to form or drive the formation of the Zn-containing barrier layer, remove impurities such as N or C, and lower the film resistivity. The Zn concentration can be tuned according to parameters such as deposition temperature, reactant dose, and pressure. Furthermore, annealing may improve adhesion of the barrier and seed layer. In some embodiments, annealing is performed at a temperature of about 300° C. or less.

Following deposition of the copper-zinc layer, as well as optional treatments of the copper-zinc layer, metal is deposited onto the copper-zinc layer and into recessed features of a metallization layer. Metal deposition, or metallization, may typically proceed via electrodeposition, also called electroplating, but in some embodiments may proceed via PVD, CVD, PECVD, ALD, or electroless deposition. During electroplating the substrate is immersed in an electroplating bath comprising metal ions along with various additives. A potential is established across the substrate, resulting in the reduction of metal ions to metal within the features. In some embodiments, electroplating proceeds by a bottom-up fill mechanism, where features are filled from the bottom of the feature towards the top, rather than from the sidewalls inward. Notably, the metal line that is deposited may be substantially without zinc. The electroplating solution may typically not contain zinc ions (or metal ions other than the metal to be plated, e.g. copper), and thus only copper will be plated. As only the copper-zinc layer contains zinc, the deposited metal line may be substantially zinc free.

### Apparatus

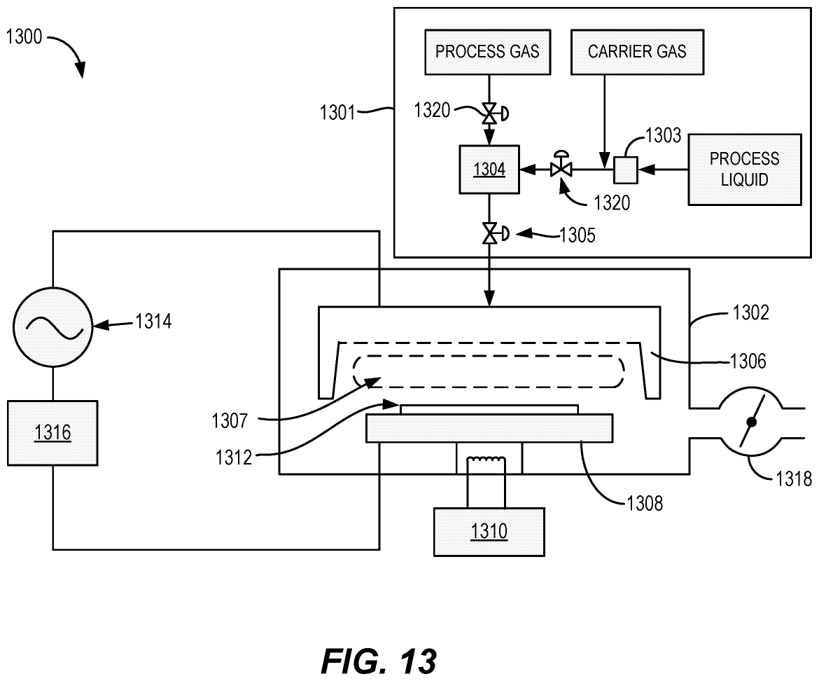

FIG. 13 schematically shows an embodiment of a process station 1300 that may be used to deposit material using atomic layer deposition (ALD) and/or chemical vapor deposition (CVD), either of which may be plasma enhanced. For simplicity, the process station 1300 is depicted as a standalone process station having a process chamber body 1302 for maintaining a low-pressure environment. However, it will be appreciated that a plurality of process stations 1300 may be included in a common process tool environment. Further, it will be appreciated that, in some embodiments, one or more hardware parameters of process station 1300, including those discussed in detail below, may be adjusted programmatically by one or more computer controllers.

Process station 1300 fluidly communicates with reactant delivery system 1301 for delivering process gases to a distribution showerhead 1306. Reactant delivery system 1301 includes a mixing vessel 1304 for blending and/or conditioning process gases for delivery to showerhead 1306. One or more mixing vessel inlet valves 1320 may control introduction of process gases to mixing vessel 1304. Similarly, a showerhead inlet valve 1305 may control introduction of process gasses to the showerhead 1306.

Some reactants, like BTBAS, may be stored in liquid form prior to vaporization at and subsequent delivery to the process station. For example, the embodiment of FIG. 13 includes a vaporization point 1303 for vaporizing liquid reactant to be supplied to mixing vessel 1304. In some embodiments, vaporization point 1303 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 1303 may be heat traced. In some examples, mixing vessel 1304 may also be heat traced. In one non-limiting example, piping downstream of vaporization point 1303 has an increasing temperature profile extending from approximately 100° C. to approximately 150° C. at mixing vessel 1304.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 1303. In one scenario, a liquid injector may be mounted directly to mixing vessel 1304. In another scenario, a liquid injector may be mounted directly to showerhead 1306.

In some embodiments, a liquid flow controller upstream of vaporization point 1303 may be provided for controlling a mass flow of liquid for vaporization and delivery to process station 1300. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 1306 distributes process gases toward substrate 1312. In the embodiment shown in FIG. 13, substrate 1312 is located beneath showerhead 1306, and is shown resting on a pedestal 1308. It will be appreciated that showerhead 1306 may have any suitable shape, and may have any suitable number and arrangement of ports for distributing processes gases to substrate 1312.

In some embodiments, a microvolume 1307 is located beneath showerhead 1306. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 1308 may be raised or lowered to expose substrate 1312 to microvolume 1307 and/or to vary a volume of microvolume 1307. For example, in a substrate transfer phase, pedestal 1308 may be lowered to allow substrate 1312 to be loaded onto pedestal 1308. During a deposition process phase, pedestal 1308 may be raised to position substrate 1312 within microvolume 1307. In some embodiments, microvolume 1307 may completely enclose substrate 1312 as well as a portion of pedestal 1308 to create a region of high flow impedance during a deposition process.

Optionally, pedestal 1308 may be lowered and/or raised during portions the deposition process to modulate process pressure, reactant concentration, etc., within microvolume 1307. In one scenario where process chamber body 1302 remains at a base pressure during the deposition process, lowering pedestal 1308 may allow microvolume 1307 to be evacuated. Example ratios of microvolume to process chamber volume include, but are not limited to, volume ratios between 1:1000 and 1:10. It will be appreciated that, in some embodiments, pedestal height may be adjusted programmatically by a suitable computer controller.

In another scenario, adjusting a height of pedestal 1308 may allow a plasma density to be varied during plasma activation and/or treatment cycles included in the deposition process. At the conclusion of the deposition process phase, pedestal 1308 may be lowered during another substrate transfer phase to allow removal of substrate 1312 from pedestal 1308.

While the example microvolume variations described herein refer to a height-adjustable pedestal, it will be appreciated that, in some embodiments, a position of showerhead 1306 may be adjusted relative to pedestal 1308 to vary a volume of microvolume 1307. Further, it will be appreciated that a vertical position of pedestal 1308 and/or showerhead 1306 may be varied by any suitable mechanism within the scope of the present disclosure. In some embodiments, pedestal 1308 may include a rotational axis for rotating an orientation of substrate 1312. It will be appreciated that, in some embodiments, one or more of these example adjustments may be performed programmatically by one or more suitable computer controllers.

Returning to the embodiment shown in FIG. 13, showerhead 1306 and pedestal 1308 electrically communicate with RF power supply 1314 and matching network 1316 for powering a plasma. In some embodiments, the plasma energy may be controlled by controlling one or more of a process station pressure, a gas concentration, an RF source power, an RF source frequency, and a plasma power pulse timing. For example, RF power supply 1314 and matching network 1316 may be operated at any suitable power to form a plasma having a desired composition of radical species. Examples of suitable powers are included above. Likewise, RF power supply 1314 may provide RF power of any suitable frequency. In some embodiments, RF power supply 1314 may be configured to control high- and low-frequency RF power sources independently of one another. Example low-frequency RF frequencies may include, but are not limited to, frequencies between 50 kHz and 1000 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 1308 may be temperature controlled via heater 1310. Further, in some embodiments, pressure control for deposition process station 1300 may be provided by butterfly valve 1318. As shown in the embodiment of FIG. 13, butterfly valve 1318 throttles a vacuum provided by a downstream vacuum pump (not shown). However, in some embodiments, pressure control of process station 1300 may also be adjusted by varying a flow rate of one or more gases introduced to process station 1300.

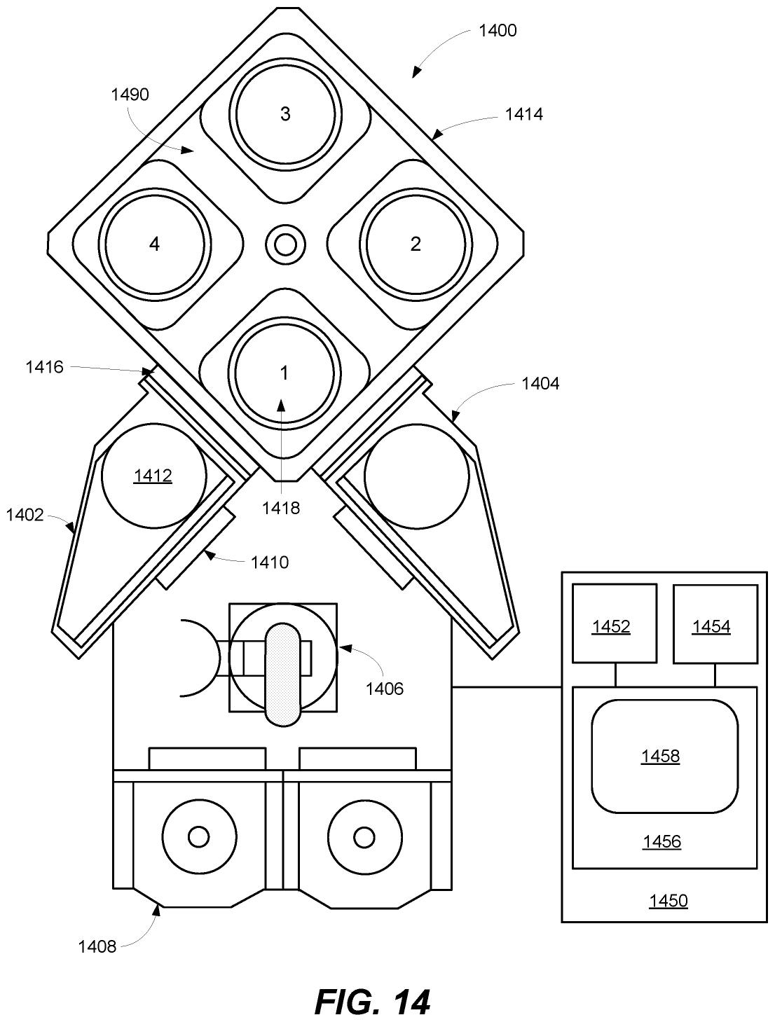

FIG. 14 shows a schematic view of an embodiment of a multi-station processing tool 1400 with an inbound load lock 1402 and an outbound load lock 1404, either or both of which may comprise a remote plasma source. A robot 1406, at atmospheric pressure, is configured to move wafers from a cassette loaded through a pod 1408 into inbound load lock 1402 via an atmospheric port 1410. A wafer is placed by the robot 1406 on a pedestal 1412 in the inbound load lock 1402, the atmospheric port 1410 is closed, and the load lock is pumped down. Where the inbound load lock 1402 comprises a remote plasma source, the wafer may be exposed to a remote plasma treatment in the load lock prior to being introduced into a processing chamber 1414. Further, the wafer also may be heated in the inbound load lock 1402 as well, for example, to remove moisture and adsorbed gases. Next, a chamber transport port 1416 to processing chamber 1414 is opened, and another robot (not shown) places the wafer into the reactor on a pedestal of a first station shown in the reactor for processing. While the embodiment depicted in FIG. 14 includes load locks, it will be appreciated that, in some embodiments, direct entry of a wafer into a process station may be provided.

The depicted processing chamber 1414 comprises four process stations, numbered from 1 to 4 in the embodiment shown in FIG. 14. Each station has a heated pedestal (shown at 1418 for station 1), and gas line inlets. It will be appreciated that in some embodiments, each process station may have different or multiple purposes. While the depicted processing chamber 1414 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 14 also depicts an embodiment of a wafer handling system 1490 for transferring wafers within processing chamber 1414. In some embodiments, wafer handling system 1490 may transfer wafers between various process stations and/or between a process station and a load lock. It will be appreciated that any suitable wafer handling system may be employed. Non-limiting examples include wafer carousels and wafer handling robots. FIG. 14 also depicts an embodiment of a system controller 1450 employed to control process conditions and hardware states of process tool 1400. System controller 1450 may include one or more memory devices 1456, one or more mass storage devices 1454, and one or more processors 1452. Processor 1452 may include a CPU or computer, analog and/or digital input/output connections, stepper motor controller boards, etc.

In some embodiments, system controller 1450 controls all of the activities of process tool 1400. System controller 1450 executes system control software 1458 stored in mass storage device 1454, loaded into memory device 1456, and executed on processor 1452. System control software 1458 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 1400. System control software 1458 may be configured in any suitable way. For example, various process tool component subroutines or control objects may be written to control operation of the process tool components necessary to carry out various process tool processes in accordance with the disclosed methods. System control software 1458 may be coded in any suitable computer readable programming language.

In some embodiments, system control software 1458 may include input/output control (IOC) sequencing instructions for controlling the various parameters described above. For example, each phase of a PEALD process may include one or more instructions for execution by system controller 1450. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 1454 and/or memory device 1456 associated with system controller 1450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1418 and to control the spacing between the substrate and other parts of process tool 1400.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 1450. The user interface may include a display screen, graphical software displays of the apparatus and/or process conditions, and user input devices such as pointing devices, keyboards, touch screens, microphones, etc.

In some embodiments, parameters adjusted by system controller 1450 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 1450 from various process tool sensors. The signals for controlling the process may be output on the analog and digital output connections of process tool 1400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, STRIKER® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

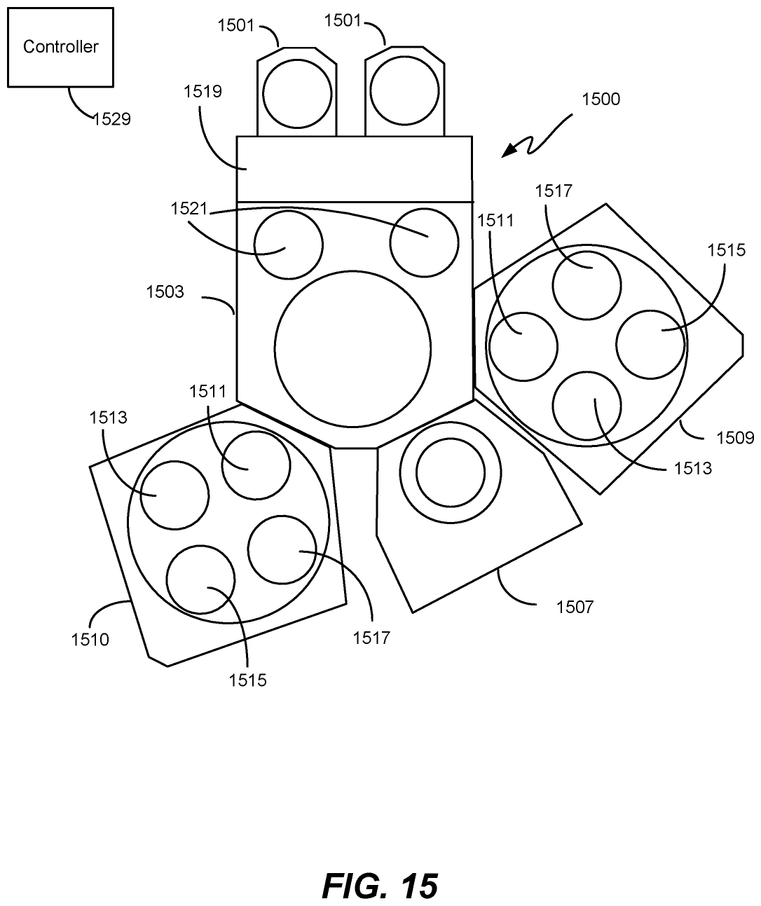

FIG. 15 is a block diagram of a processing system suitable for conducting thin film deposition processes in accordance with certain embodiments. The system 1500 includes a transfer module 1503. The transfer module 1503 provides a clean, pressurized environment to minimize risk of contamination of substrates being processed as they are moved between various reactor modules. Mounted on the transfer module 1503 are two multi-station reactors 1509 and 1510, each capable of performing atomic layer deposition (ALD) and/or chemical vapor deposition (CVD) according to certain embodiments. Reactors 1509 and 1510 may include multiple stations 1511, 1513, 1515, and 1517 that may sequentially or non-sequentially perform operations in accordance with disclosed embodiments. The stations may include a heated pedestal or substrate support, one or more gas inlets or showerhead or dispersion plate.

Also mounted on the transfer module 1503 may be one or more single or multi-station modules 1507 capable of performing plasma or chemical (non-plasma) pre-cleans, or any other processes described in relation to the disclosed methods. The module 1507 may in some cases be used for various treatments to, for example, prepare a substrate for a deposition process. The module 1507 may also be designed/configured to perform various other processes such as etching or polishing. The system 1500 also includes one or more wafer source modules 1501, where wafers are stored before and after processing. An atmospheric robot (not shown) in the atmospheric transfer chamber 1519 may first remove wafers from the source modules 1501 to loadlocks 1521. A wafer transfer device (generally a robot arm unit) in the transfer module 1503 moves the wafers from loadlocks 1521 to and among the modules mounted on the transfer module 1503.

In various embodiments, a system controller 1529 is employed to control process conditions during deposition. The controller 1529 will typically include one or more memory devices and one or more processors. A processor may include a CPU or computer, analog and/or digital input/output connections, stepper motor controller boards, etc.

The controller 1529 may control all of the activities of the deposition apparatus. The system controller 1529 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1529 may be employed in some embodiments.

Typically there will be a user interface associated with the controller 1529. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the copper-containing precursor pulses, hydrogen flow, and zinc-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 1529. The signals for controlling the process are output on the analog and digital output connections of the deposition apparatus 1500.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

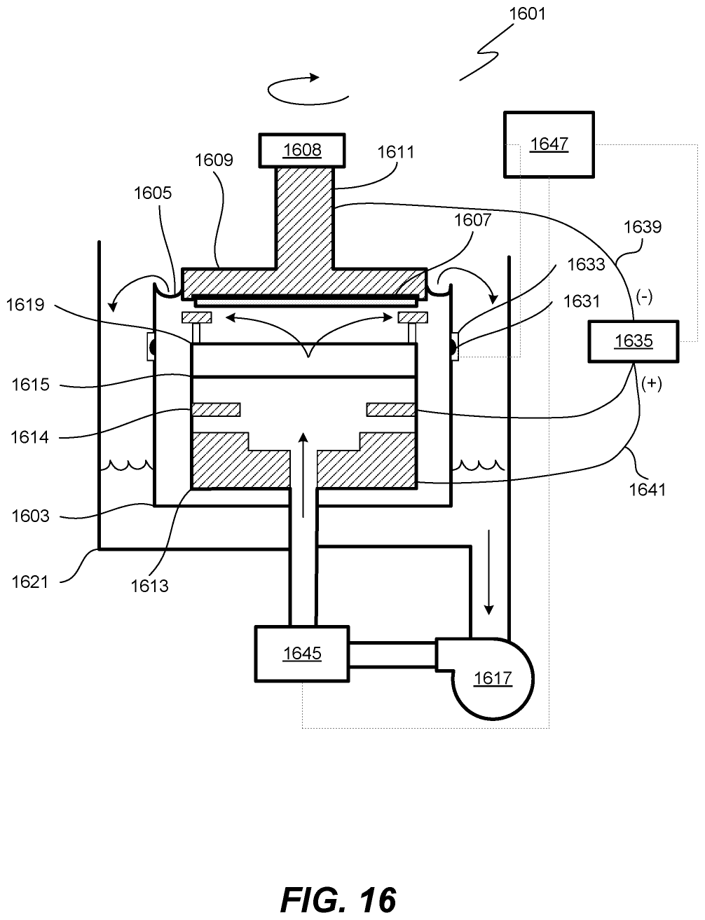

FIG. 16 presents an example of an electroplating cell in which electroplating may occur. Often, an electroplating apparatus includes one or more electroplating cells in which the substrates (e.g., wafers) are processed. Only one electroplating cell is shown in FIG. 16 to preserve clarity. To optimize bottom-up electroplating, additives (e.g., accelerators, suppressors, and levelers) are added to the electrolyte; however, an electrolyte with additives may react with the anode in undesirable ways. Therefore anodic and cathodic regions of the plating cell are sometimes separated by a membrane so that plating solutions of different composition may be used in each region. Plating solution in the cathodic region is called catholyte; and in the anodic region, anolyte. A number of engineering designs can be used in order to introduce anolyte and catholyte into the plating apparatus.

Referring to FIG. 16, a diagrammatical cross-sectional view of an electroplating apparatus 1601 in accordance with one embodiment is shown. The plating bath 1603 contains the plating solution (having a composition as provided herein), which is shown at a level 1605. The catholyte portion of this vessel is adapted for receiving substrates in a catholyte. A wafer 1607 is immersed into the plating solution and is held by, e.g., a “clamshell” substrate holder 1609, mounted on a rotatable spindle 1611, which allows rotation of clamshell substrate holder 1609 together with the wafer 1607. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated herein by reference in their entireties.

An anode 1613 is disposed below the wafer within the plating bath 1603 and is separated from the wafer region by a membrane 1615, preferably an ion selective membrane. For example, Nafion™ cationic exchange membrane (CEM) may be used. The region below the anodic membrane is often referred to as an “anode chamber.” The ion-selective anode membrane 1615 allows ionic communication between the anodic and cathodic regions of the plating cell, while preventing the particles generated at the anode from entering the proximity of the wafer and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated herein by reference in their entireties. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating the ions from the plating solution are deposited on the substrate. The metal ions must diffuse through the diffusion boundary layer and into the TSV hole or other feature. A typical way to assist the diffusion is through convection flow of the electroplating solution provided by the pump 1617. Additionally, a vibration agitation or sonic agitation member may be used as well as wafer rotation. For example, a vibration transducer 1608 may be attached to the clamshell substrate holder 1609.

The plating solution is continuously provided to plating bath 1603 by the pump 1617. Generally, the plating solution flows upwards through an anode membrane 1615 and a diffuser plate 1619 to the center of wafer 1607 and then radially outward and across wafer 1607. The plating solution also may be provided into the anodic region of the bath from the side of the plating bath 1603. The plating solution then overflows plating bath 1603 to an overflow reservoir 1621. The plating solution is then filtered (not shown) and returned to pump 1617 completing the recirculation of the plating solution. In certain configurations of the plating cell, a distinct electrolyte is circulated through the portion of the plating cell in which the anode is contained while mixing with the main plating solution is prevented using sparingly permeable membranes or ion selective membranes.

A reference electrode 1631 is located on the outside of the plating bath 1603 in a separate chamber 1633, which chamber is replenished by overflow from the main plating bath 1603. Alternatively, in some embodiments the reference electrode is positioned as close to the substrate surface as possible, and the reference electrode chamber is connected via a capillary tube or by another method, to the side of the wafer substrate or directly under the wafer substrate. In some of the preferred embodiments, the apparatus further includes contact sense leads that connect to the wafer periphery and which are configured to sense the potential of the metal seed layer at the periphery of the wafer but do not carry any current to the wafer.

A reference electrode 1631 is typically employed when electroplating at a controlled potential is desired. The reference electrode 1631 may be one of a variety of commonly used types such as mercury/mercury sulfate, silver chloride, saturated calomel, or copper metal. A contact sense lead in direct contact with the wafer 1607 may be used in some embodiments, in addition to the reference electrode, for more accurate potential measurement (not shown).

A DC power supply 1635 can be used to control current flow to the wafer 1607. The power supply 1635 has a negative output lead 1639 electrically connected to wafer 1607 through one or more slip rings, brushes and contacts (not shown). The positive output lead 1641 of power supply 1635 is electrically connected to an anode 1613 located in plating bath 1603. The power supply 1635, a reference electrode 1631, and a contact sense lead (not shown) can be connected to a system controller 1647, which allows, among other functions, modulation of current and potential provided to the elements of electroplating cell. For example, the controller may allow electroplating in potential-controlled and current-controlled regimes. The controller may include program instructions specifying current and voltage levels that need to be applied to various elements of the plating cell, as well as times at which these levels need to be changed. When forward current is applied, the power supply 1635 biases the wafer 1607 to have a negative potential relative to anode 1613. This causes an electrical current to flow from anode 1613 to the wafer 1607, and an electrochemical reduction (e.g. Cu²⁺+2 e⁻=Cu⁰) occurs on the wafer surface (the cathode), which results in the deposition of the electrically conductive layer (e.g. copper) on the surfaces of the wafer. An inert anode 1614 may be installed below the wafer 1607 within the plating bath 1603 and separated from the wafer region by the membrane 1615.

The apparatus may also include a heater 1645 for maintaining the temperature of the plating solution at a specific level. The plating solution may be used to transfer the heat to the other elements of the plating bath. For example, when a wafer 1607 is loaded into the plating bath the heater 1645 and the pump 1617 may be turned on to circulate the plating solution through the electroplating apparatus 1601, until the temperature throughout the apparatus becomes substantially uniform. In one embodiment the heater is connected to the system controller 1647. The system controller 1647 may be connected to a thermocouple to receive feedback of the plating solution temperature within the electroplating apparatus and determine the need for additional heating.

The controller will typically include one or more memory devices and one or more processors. The processor may include a CPU or computer, analog and/or digital input/output connections, stepper motor controller boards, etc. In certain embodiments, the controller controls all of the activities of the electroplating apparatus. Non-transitory machine-readable media containing instructions for controlling process operations in accordance with the present embodiments may be coupled to the system controller.

Typically there will be a user interface associated with controller 1647. The user interface may include a display screen, graphical software displays of the apparatus and/or process conditions, and user input devices such as pointing devices, keyboards, touch screens, microphones, etc. The computer program code for controlling electroplating processes can be written in any conventional computer readable programming language: for example, assembly language, C, C++, Pascal, Fortran or others. Compiled object code or script is executed by the processor to perform the tasks identified in the program. One example of a plating apparatus that may be used according to the embodiments herein is the Lam Research Sabre tool. Electrodeposition can be performed in components that form a larger electrodeposition apparatus.

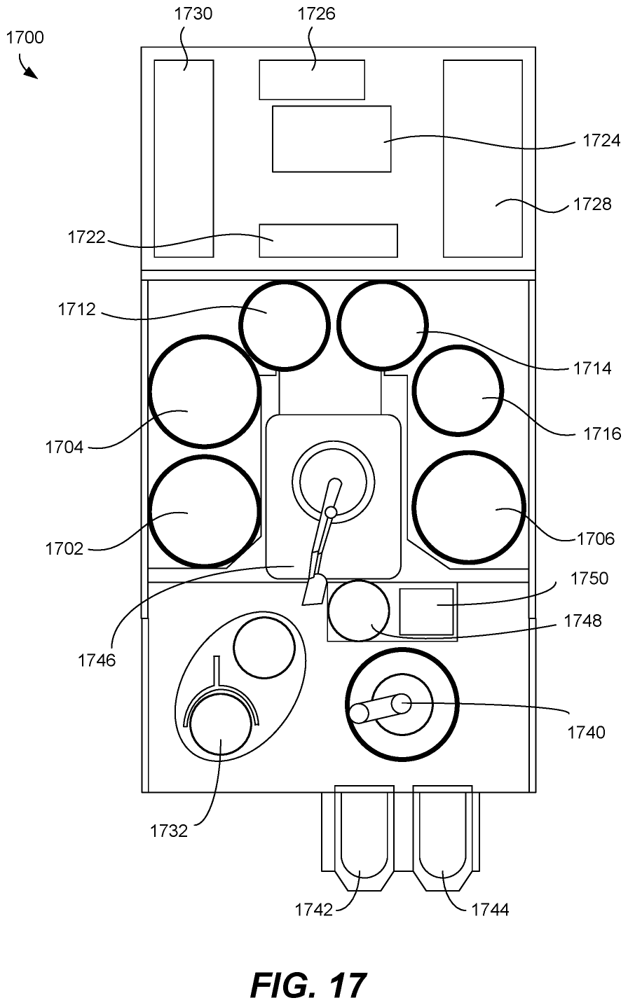

FIG. 17 shows a schematic of a top view of an example electrodeposition apparatus. The electrodeposition apparatus 1700 can include three separate electroplating modules 1702, 1704, and 1706. The electrodeposition apparatus 1700 can also include three separate modules 1712, 1714, and 1716 configured for various process operations. For example, in some embodiments, one or more of modules 1712, 1714, and 1716 may be a spin rinse drying (SRD) module. In other embodiments, one or more of the modules 1712, 1714, and 1716 may be post-electrofill modules (PEMs), each configured to perform a function, such as edge bevel removal, backside etching, and acid cleaning of substrates after they have been processed by one of the electroplating modules 1702, 1704, and 1706.

The electrodeposition apparatus 1700 includes a central electrodeposition chamber 1724. The central electrodeposition chamber 1724 is a chamber that holds the chemical solution used as the electroplating solution in the electroplating modules 1702, 1704, and 1706. The electrodeposition apparatus 1700 also includes a dosing system 1726 that may store and deliver additives for the electroplating solution. A chemical dilution module 1722 may store and mix chemicals to be used as an etchant. A filtration and pumping unit 1728 may filter the electroplating solution for the central electrodeposition chamber 1724 and pump it to the electroplating modules.

A system controller 1730 provides electronic and interface controls required to operate the electrodeposition apparatus 1700. The system controller 1730 (which may include one or more physical or logical controllers) controls some or all of the properties of the electroplating apparatus 1700.

Signals for monitoring the process may be provided by analog and/or digital input connections of the system controller 1730 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

A hand-off tool 1740 may select a substrate from a substrate cassette such as the cassette 1742 or the cassette 1744. The cassettes 1742 or 1744 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 1740 may hold the substrate using a vacuum attachment or some other attaching mechanism.

The hand-off tool 1740 may interface with a wafer handling station 1732, the cassettes 1742 or 1744, a transfer station 1750, or an aligner 1748. From the transfer station 1750, a hand-off tool 1746 may gain access to the substrate. The transfer station 1750 may be a slot or a position from and to which hand-off tools 1740 and 1746 may pass substrates without going through the aligner 1748. In some embodiments, however, to ensure that a substrate is properly aligned on the hand-off tool 1746 for precision delivery to an electroplating module, the hand-off tool 1746 may align the substrate with an aligner 1748. The hand-off tool 1746 may also deliver a substrate to one of the electroplating modules 1702, 1704, or 1706 or to one of the three separate modules 1712, 1714, and 1716 configured for various process operations.

An example of a process operation according to the methods described above may proceed as follows: (1) electrodeposit copper or another material onto a substrate in the electroplating module 1704; (2) rinse and dry the substrate in SRD in module 1712; and, (3) perform edge bevel removal in module 1714.

An apparatus configured to allow efficient cycling of substrates through sequential plating, rinsing, drying, and PEM process operations may be useful for implementations for use in a manufacturing environment. To accomplish this, the module 1712 can be configured as a spin rinse dryer and an edge bevel removal chamber. With such a module 1712, the substrate would only need to be transported between the electroplating module 1704 and the module 1712 for the copper plating and EBR operations. In some embodiments the methods described herein will be implemented in a system which comprises an electroplating apparatus and a stepper.

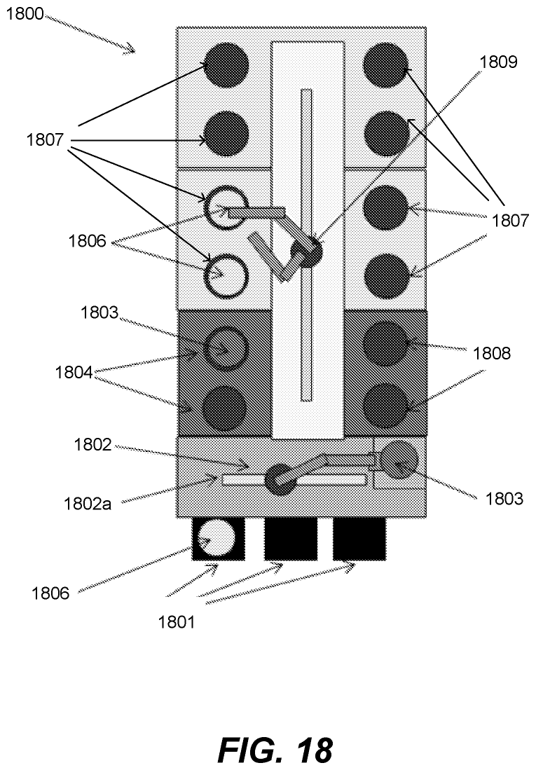

An alternative embodiment of an electrodeposition apparatus 1800 is schematically illustrated in FIG. 18. In this embodiment, the electrodeposition apparatus 1800 has a set of electroplating cells 1807, each containing an electroplating bath, in a paired or multiple “duet” configuration. In addition to electroplating per se, the electrodeposition apparatus 1800 may perform a variety of other electroplating related processes and sub-steps, such as spin-rinsing, spin-drying, metal and silicon wet etching, electroless deposition, pre-wetting and pre-chemical treating, reducing, annealing, electro-etching and/or electropolishing, photoresist stripping, and surface pre-activation, for example. The electrodeposition apparatus 1800 is shown schematically looking top down in FIG. 18, and only a single level or “floor” is revealed in the figure, but it is to be readily understood by one having ordinary skill in the art that such an apparatus, e.g., the Lam Sabre™ 3D tool, can have two or more levels “stacked” on top of each other, each potentially having identical or different types of processing stations.

Referring once again to FIG. 18, the substrates 1806 that are to be electroplated are generally fed to the electrodeposition apparatus 1800 through a front end loading FOUP 1801 and, in this example, are brought from the FOUP to the main substrate processing area of the electrodeposition apparatus 1800 via a front-end robot 1802 that can retract and move a substrate 1806 driven by a spindle 1803 in multiple dimensions from one station to another of the accessible stations—two front-end accessible stations 1804 and also two front-end accessible stations 1808 are shown in this example. The front-end accessible stations 1804 and 1808 may include, for example, pre-treatment stations, and spin rinse drying (SRD) stations. Lateral movement from side-to-side of the front-end robot 1802 is accomplished utilizing robot track 1802a. Each of the substrates 1806 may be held by a cup/cone assembly (not shown) driven by a spindle 1803 connected to a motor (not shown), and the motor may be attached to a mounting bracket 1809. Also shown in this example are the four “duets” of electroplating cells 1807, for a total of eight electroplating cells 1807. A system controller (not shown) may be coupled to the electrodeposition apparatus 1800 to control some or all of the properties of the electrodeposition apparatus 1800. The system controller may be programmed or otherwise configured to execute instructions according to processes described earlier herein.

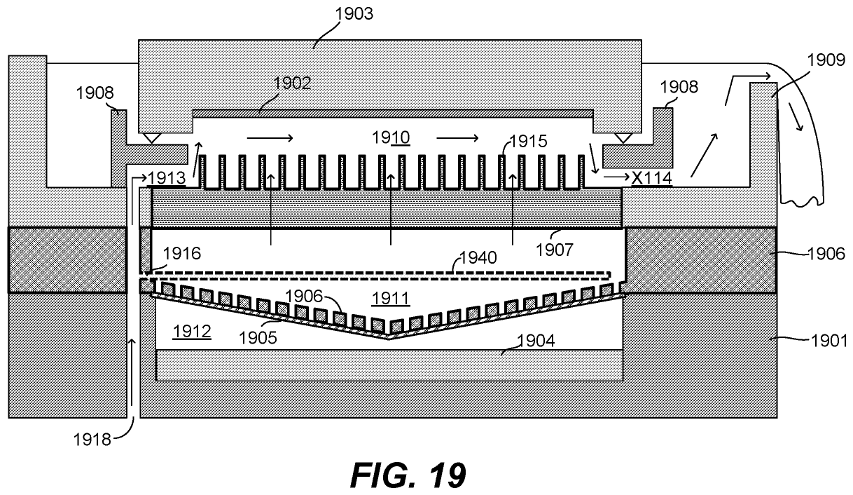

FIG. 19 depicts a simplified cross-sectional view of an electroplating apparatus. The apparatus includes an electroplating cell 1901, with substrate 1902 positioned in a substrate holder 1903. Substrate holder 1903 is often referred to as a cup, and it may support the substrate 1902 at its periphery. An anode 1904 is positioned near the bottom of the electroplating cell 1901. The anode 1904 is separated from the substrate 1902 by a membrane 1905, which is supported by a membrane frame 1906. Membrane frame 1906 is sometimes referred to as an anode chamber membrane frame, as it defines the top of the anode chamber housing the anode. Further, the anode 1904 is separated from the substrate 1902 by an ionically resistive element 1907. The ionically resistive element 1907 includes openings that allow electrolyte to travel through the ionically resistive element 1907 to impinge upon the substrate 1902. A front side insert 1908 is positioned above the ionically resistive element 1907, proximate the periphery of the substrate 1902. The front side insert 1908 may be ring-shaped, and may be azimuthally non-uniform, as shown. The front side insert 1908 is sometimes also referred to as a cross flow confinement ring.

An anode chamber 1912 is below the membrane 1905, and is where the anode 1904 is located. An ionically resistive element manifold 1911 is above the membrane 1905 and below the ionically resistive element 1907. An inlet 1916, which may be connected with an irrigation flute 1940, delivers catholyte to the ionically resistive element manifold 1911, and may act to irrigate the membrane 1905 during electroplating. In this example, the inlet 1916 and irrigation flute 1940 are fed by electrolyte that passes through catholyte inlet 1918. A cross flow manifold 1910 is above the ionically resistive element 1907 and below the substrate 1902. The height of the cross flow manifold is considered to be the distance between the substrate 1902 and the plane of the ionically resistive element 1907 (excluding the ribs 1915 on the upper surface of the ionically resistive element 1907, if present). In some cases, the cross flow manifold may have a height between about 1 mm-4 mm, or between about 0.5 mm-15 mm. The cross flow manifold 1910 is defined on its sides by the front side insert 1908, which acts to contain the cross flowing electrolyte within the cross flow manifold 1910. A side inlet 1913 to the cross flow manifold 1910 is provided azimuthally opposite a side outlet 1914 to the cross flow manifold 1910. The side inlet 1913 and side outlet 1914 may be formed, at least partially, by the front side insert 1908. As shown by the arrows in FIG. 19, electrolyte travels from the catholyte inlet 1918, through the side inlet 1913, into the cross flow manifold 1910, and out the side outlet 1914. In addition, electrolyte may travel through one or more inlets to the ionically resistive element manifold 1911 (e.g., inlets in irrigation flute 1940 and/or other inlets), into the ionically resistive element manifold 1911, through the openings in the ionically resistive element 1907, into the cross flow manifold 1910, and out the side outlet 1914. After passing through the side outlet 1914, the electrolyte spills over weir wall 1909. The electrolyte may be recovered and recycled.

In certain embodiments, the ionically resistive element 1907 approximates a nearly constant and uniform current source in the proximity of the substrate (cathode) and, as such, may be referred to as a high resistance virtual anode (HRVA) or channeled ionically resistive element (CIRP) in some contexts. Normally, the ionically resistive element 1907 is placed in close proximity with respect to the wafer. In contrast, an anode in the same close-proximity to the substrate would be significantly less apt to supply a nearly constant current to the wafer, but would merely support a constant potential plane at the anode metal surface, thereby allowing the current to be greatest where the net resistance from the anode plane to the terminus (e.g., to peripheral contact points on the wafer) is smaller. So while the ionically resistive element 1907 has been referred to as a high-resistance virtual anode (HRVA), this does not imply that electrochemically the two are interchangeable. Under certain operational conditions, the ionically resistive element 1907 would more closely approximate and perhaps be better described as a virtual uniform current source, with nearly constant current being sourced from across the upper plane of the ionically resistive element 1907.

The ionically resistive element 1907 contains micro size (typically less than 0.04″) through-holes that are spatially and ionically isolated from each other and do not form interconnecting channels within the body of ionically resistive element, in many but not all implementations. Such through-holes are often referred to as non-communicating through-holes. They typically extend in one dimension, often, but not necessarily, normal to the plated surface of the wafer (in some embodiments the non-communicating holes are at an angle with respect to the wafer which is generally parallel to the ionically resistive element front surface). Often the through-holes are parallel to one another. Often the holes are arranged in a square array. Other times the layout is in an offset spiral pattern. These through-holes are distinct from 3-D porous networks, where the channels extend in three dimensions and form interconnecting pore structures, because the through-holes restructure both ionic current flow and (in certain cases) fluid flow parallel to the surface therein, and straighten the path of both current and fluid flow towards the wafer surface. However, in certain embodiments, such a porous plate, having an interconnected network of pores, may be used as the ionically resistive element. When the distance from the plate's top surface to the wafer is small (e.g., a gap of about 1/10 the size of the wafer radius, for example less than about 5 mm), divergence of both current flow and fluid flow is locally restricted, imparted and aligned with the ionically resistive element channels.

One example ionically resistive element 1907 is a disc made of a solid, non-porous dielectric material that is ionically and electrically resistive. The material is also chemically stable in the plating solution of use. In certain cases the ionically resistive element 1907 is made of a ceramic material (e.g., aluminum oxide, stannic oxide, titanium oxide, or mixtures of metal oxides) or a plastic material (e.g., polyethylene, polypropylene, polyvinylidene difluoride (PVDF), polytetrafluoroethylene, polysulphone, polyvinyl chloride (PVC), polycarbonate, and the like), having between about 6,000-12,000 non-communicating through-holes. The ionically resistive element 1907, in many embodiments, is substantially coextensive with the wafer (e.g., the ionically resistive element 1907 has a diameter of about 300 mm when used with a 300 mm wafer) and resides in close proximity to the wafer, e.g., just below the wafer in a wafer-facing-down electroplating apparatus. Preferably, the plated surface of the wafer resides within about 10 mm, more preferably within about 5 mm of the closest ionically resistive element surface. To this end, the top surface of the ionically resistive element 1907 may be flat or substantially flat. Often, both the top and bottom surfaces of the ionically resistive element 1907 are flat or substantially flat. In a number of embodiments, however, the top surface of the ionically resistive element 1907 includes a series of linear ribs, as described further below.

As above, the overall ionic and flow resistance of the plate 1907 is dependent on the thickness of the plate and both the overall porosity (fraction of area available for flow through the plate) and the size/diameter of the holes. Plates of lower porosities will have higher impinging flow velocities and ionic resistances. Comparing plates of the same porosity, one having smaller diameter 1-D holes (and therefore a larger number of 1-D holes) will have a more micro-uniform distribution of current on the wafer because there are more individual current sources, which act more as point sources that can spread over the same gap, and will also have a higher total pressure drop (high viscous flow resistance).

In some cases, about 1-10% of the ionically resistive element 1907 is open area through which ionic current can pass (and through which electrolyte can pass if there is no other element blocking the openings). In particular embodiments, about 2-5% the ionically resistive element 1907 is open area. In a specific example, the open area of the ionically resistive element 1907 is about 3.2% and the effective total open cross sectional area is about 23 cm². In some embodiments, non-communicating holes formed in the ionically resistive element 1907 have a diameter of about 0.01 to 0.08 inches. In some cases, the holes have a diameter of about 0.02 to 0.03 inches, or between about 0.03-0.06 inches. In various embodiments the holes have a diameter that is at most about 0.2 times the gap distance between the ionically resistive element 1907 and the wafer. The holes are generally circular in cross section, but need not be. Further, to ease construction, all holes in the ionically resistive element 1907 may have the same diameter. However this need not be the case, and both the individual size and local density of holes may vary over the ionically resistive element surface as specific requirements may dictate.

The ionically resistive element 1907 shown in FIG. 19 includes a series of linear ribs 1915 that extend into/out of the page. The ribs 1915 are sometimes referred to as protuberances. The ribs 1915 are positioned on the top surface of the ionically resistive element 1907, and in many cases they are oriented such that their length (e.g., their longest dimension) is perpendicular to the direction of cross flowing electrolyte. In a particular embodiment, the ribs 1915 may be oriented such that their length is parallel to the direction of cross flowing electrolyte. The ribs 1915 affect the fluid flow and current distribution within the cross flow manifold 1910. For instance, the cross flow of electrolyte is largely confined to the area above the top surface of the ribs 1915, creating a high rate of electrolyte cross flow in this area. In the regions between adjacent ribs 1915, current delivered upward through the ionically resistive element 1907 is redistributed, becoming more uniform, before it is delivered to the substrate surface.

In FIG. 19, the direction of cross flowing electrolyte is left-to-right (e.g., from the side inlet 1913 to the side outlet 1914), and the ribs 1915 are oriented such that their lengths extend into/out of the page. In certain embodiments, the ribs 1915 may have a width (measured left-to-right in FIG. 19) between about 0.5 mm-1.5 mm, or between about 0.25 mm-10 mm. The ribs 1915 may have a height (measured up-down in FIG. 19) between about 1.5 mm-3.0 mm, or between about 0.25 mm-7.0 mm. The ribs 1915 may have a height to width aspect ratio (height/width) between about 5/1-2/1, or between about 7/1-1/7. The ribs 1915 may have a pitch between about 10 mm-30 mm, or between about 5 mm-150 mm. The ribs 1915 may have variable lengths (measured into/out of the page in FIG. 19) that extend across the face of the ionically resistive element 1907. The distance between the upper surface of the ribs 1915 and the surface of the substrate 1902 may be between about 1 mm-4 mm, or between about 0.5 mm-15 mm. The ribs 1915 may be provided over an area that is about coextensive with the substrate, as shown in FIG. 19. The channels/openings in the ionically resistive element 1907 may be positioned between adjacent ribs 1915, or they may extend through the ribs 1915 (in other words, the ribs 1915 may or may not be channeled). In some other embodiments, the ionically resistive element 1907 may have an upper surface that is flat (e.g., does not include the ribs 1915). The electroplating apparatus shown in FIG. 19, including the ionically resistive element with ribs thereon, is further discussed in U.S. Pat. No. 9,523,155, titled “ENHANCEMENT OF ELECTROLYTE HYDRODYNAMICS FOR EFFICIENT MASS TRANSFER DURING ELECTROPLATING,” which is herein incorporated by reference in its entirety.

The apparatus may include various additional elements as needed for a particular application. In some cases, an edge flow element may be provided proximate the periphery of the substrate, within the cross flow manifold. The edge flow element may be shaped and positioned to promote a high degree of electrolyte flow (e.g., cross flow) near the edges of the substrate. The edge flow element may be ring-shaped or arc-shaped in certain embodiments, and may be azimuthally uniform or non-uniform. Edge flow elements are further discussed in U.S. patent application Ser. No. 14/924,124, filed Oct. 27, 2015, and titled “EDGE FLOW ELEMENT FOR ELECTROPLATING APPARATUS,” which is herein incorporated by reference in its entirety.

In some cases, the apparatus may include a sealing member for temporarily sealing the cross flow manifold. The sealing member may be ring-shaped or arc-shaped, and may be positioned proximate the edges of the cross flow manifold. A ring-shaped sealing member may seal the entire cross flow manifold, while an arc-shaped sealing member may seal a portion of the cross flow manifold (in some cases leaving the side outlet open). During electroplating, the sealing member may be repeatedly engaged and disengaged to seal and unseal the cross flow manifold. The sealing member may be engaged and disengaged by moving the substrate holder, ionically resistive element, front side insert, or other portion of the apparatus that engages with the sealing member. Sealing members and methods of modulating cross flow are further discussed in the following U.S. Patent Applications, each of which is herein incorporated by reference in its entirety: U.S. patent application Ser. No. 15/225,716, filed Aug. 1, 2016, and titled “DYNAMIC MODULATION OF CROSS FLOW MANIFOLD DURING ELECTROPLATING”; and U.S. patent application Ser. No. 15/161,081, filed May 20, 2016, and titled “DYNAMIC MODULATION OF CROSS FLOW MANIFOLD DURING ELECTROPLATING.”

In various embodiments, one or more electrolyte jet may be provided to deliver additional electrolyte above the ionically resistive element. The electrolyte jet may deliver electrolyte proximate a periphery of the substrate, or at a location that is closer to the center of the substrate, or both. The electrolyte jet may be oriented in any position, and may deliver cross flowing electrolyte, impinging electrolyte, or a combination thereof. Electrolyte jets are further described in U.S. patent application Ser. No. 15/455,011, filed Mar. 9, 2017, and titled “ELECTROPLATING APPARATUS AND METHODS UTILIZING INDEPENDENT CONTROL OF IMPINGING ELECTROLYTE,” which is herein incorporated by reference in its entirety.

In some implementations, a controller 1229, a controller 1347, and/or a controller 1430, are part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1229, controller 1347, and/or controller 1430, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
(a) receiving a metallization layer having recessed features within a dielectric layer comprising a dielectric material;
(b) conformally depositing one or more layers collectively comprising copper and zinc over the recessed features, wherein conformally depositing at least one layer of the one or more layers comprises a copper atomic layer deposition (ALD) process; and
(c) filling the recessed features with a metal.

2. The method of claim 1, further comprising causing zinc to diffuse from the one or more layers into the dielectric layer.

3. The method of claim 1, further comprising, prior to forming the metal layer in the recessed features, annealing the one or more layers at a temperature of at most about 250° C.

4. The method of claim 3, wherein annealing the one or more layers is performed in the presence of hydrogen.

5. The method of claim 1, wherein the one or more layers are electrically conductive and wherein at least one of the one or more layers provides a barrier to diffusion of metal ions from a metal layer to the dielectric material.

6. The method of claim 1, further comprising forming a zinc silicate layer between the dielectric layer and the one or more layers.

7. The method of claim 6, wherein the zinc silicate layer inhibits the diffusion of copper into the dielectric layer.

8. The method of claim 6, wherein forming the zinc silicate layer occurs within the dielectric layer and/or at the interface of the dielectric layer and the one or more layers while conformally depositing the one or more layers over the recessed features.

9. The method of claim 6, wherein forming the zinc silicate layer occurs within the dielectric layer and/or at the interface of the dielectric layer and the one or more layers after conformally depositing the one or more layers over the recessed features.

10. The method of claim 6, wherein the zinc silicate layer is about 2 nm thick or thinner.

11. The method of claim 1, further comprising forming a zinc oxide layer disposed on top of the one or more layers.

12. The method of claim 11, wherein forming the zinc oxide layer comprises exposing the one or more layers to the atmosphere.

13. The method of claim 1, wherein conformally depositing the one or more layers comprises depositing a copper-zinc alloy by a copper-zinc ALD process.

14. The method of claim 13, wherein the copper-zinc ALD process comprises:
exposing the substrate to a zinc precursor,
purging the zinc precursor,
exposing the substrate to a copper precursor, and
purging the copper precursor.

15. The method of claim 1, wherein conformally depositing the one or more layers comprises:
exposing the substrate to a zinc precursor,
purging the zinc precursor,
exposing the substrate to a copper precursor,
purging the copper precursor,
exposing the substrate to a nitrogen containing reactant, and
purging the nitrogen containing reactant.

16. The method of claim 1, wherein conformally depositing the one or more layers comprises:
exposing the substrate to a copper precursor,
purging the copper precursor,
exposing the substrate to a nitrogen-containing reactant, and
purging the nitrogen-containing reactant, and
depositing zinc by a chemical vapor deposition (CVD) process in the presence of hydrogen.

17. The method of claim 1, wherein conformally depositing the one or more layers comprises:
(a) depositing a first zinc layer on the dielectric material, and
(b) depositing a copper layer by an ALD process.

18. The method of claim 17, wherein conformally depositing the one or more layers further comprises (c) depositing a second zinc layer on the copper layer.

19. The method of claim 1, wherein conformally depositing the one or more layers comprises:
(a) exposing the substrate to a zinc precursor,
(b) purging the zinc precursor,
(c) exposing the substrate to a copper precursor,
(d) purging the copper precursor, and
(e) repeating (a)-(d) one or more times to form a copper-zinc layer, and
(f) depositing a zinc layer.

20. The method of claim 14, wherein the zinc precursor is a dialkyl zinc.

21. The method of claim 14, wherein the copper precursor comprises a bidentate ligand bound to copper via at least one oxygen atom.

22. The method of claim 1, further comprising, prior to depositing the one or more layers, conformally depositing a liner layer over the recessed features.

23. The method of claim 22, wherein the liner layer comprises at least one material chosen from the group consisting of: zinc, tantalum, titanium, tungsten, molybdenum, and their nitrides, carbides, and carbonitrides.

24. The method of claim 1, wherein filling the recessed features is performed by an electrodeposition process.

25. The method of claim 1, wherein the metal is copper that is substantially free of zinc.

26. The method of claim 1, wherein at least some of the recessed features have an aspect ratio of at least about 5:1.

27. The method of claim 26, wherein at least some of the recessed features having an aspect ratio of at least about 5:1 have a width or diameter of about 20 nm or smaller.

28. The method of claim 1, wherein the dielectric material has a dielectric constant of about 3.0 or lower.

29. A device, comprising:
a dielectric layer comprising a dielectric material and having recessed features, wherein at least some of the recessed features have a critical dimension of about 20 nm or smaller;
one or more layers comprising at least one of copper and zinc conformally formed in the dielectric layer; and
electrically conductive material formed in the recessed features, wherein the electrically conductive material is substantially zinc-free.

30. An apparatus, comprising:
a reaction chamber configured to hold a substrate during a conformal deposition reaction on a substrate having recessed features within a dielectric layer comprising a dielectric material; and
a controller that includes one or more processors and one or more memory devices, wherein the one or more memory devices store computer-executable instructions for controlling the one or more processors to:
(a) receive the substrate in the reaction chamber;
(b) conformally deposit one or more layers collectively comprising copper and zinc over the recessed features, wherein conformally depositing at least one layer of the one or more layers comprises a copper atomic layer deposition (ALD) process; and
(c) transfer the substrate to an electroplating cell.
